(19) United States
(12) Patent Application Publication
(10) Pub. No.: US 2026/0181874 A1
(43) Pub. Date: Jun. 25, 2026

(54) SEMICONDUCTOR DEVICE

(71) Applicant: Samsung Electronics Co., Ltd., Suwon-si (KR)

(72) Inventor: Taemin CHA, Suwon-si (KR)

(73) Assignee: Samsung Electronics Co., Ltd., Suwon-si (KR)

(21) Appl. No.: 19/273,861

(22) Filed: Jul. 18, 2025

(30) Foreign Application Priority Data
Dec. 20, 2024 (KR) 10-2024-0193162

(51) Int. Cl. H10B 12/00

(52) U.S. Cl. CPC H10B 12/488; H10B 12/05; H10B 12/315

(57) ABSTRACT

The present disclosure relates to a semiconductor device, and a semiconductor device according to at least one example embodiment includes a substrate, a bit line on the substrate, a plurality of word lines on the bit line, first and second active patterns between the plurality of word lines and spaced apart in the first direction, at least one cell capacitor on at least one of the first active pattern or the second active pattern, and a plurality of shield patterns above the plurality of word lines and below the cell capacitor. The plurality of shield patterns overlaps the second dopant region of at least one of the first active pattern or the second active pattern in the first direction, and the plurality of shield patterns includes at least one of metal-containing materials having an n-type work function or polysilicon doped with an impurity.

### CROSS-REFERENCE TO RELATED APPLICATION

This application claims priority to and the benefit of Korean Patent Application No. 10-2024-0193162 filed with the Korean Intellectual Property Office on Dec. 20, 2024, the entire contents of which are incorporated herein by reference.

### BACKGROUND

### 1. Field

The present disclosure relates to a semiconductor device.

### 2. Description of the Related Art

Due to greater demand for higher integration technologies to increase the degrees of integration of semiconductor devices are being explored. In the case of two-dimensional memory (or semiconductor) devices, the degrees of integration are mainly determined by the areas occupied by unit memory cells, and the degrees of integration in this aspect may depend on the levels of micropatterning techniques.

However, the micropatterning techniques generally require expensive equipment. Therefore, although the degrees of integration of two-dimensional semiconductor devices are increasing, such techniques are often still limited due to the increase in cost. Accordingly, three-dimensional memory devices having memory cells arranged in three dimensions are being explored.

As components which are included in semiconductor memory devices become more integrated and/or miniaturized, it may be advantageous to reduce and/or minimize the influence between components included in semiconductor devices to improve the operating performance of the semiconductor devices.

### SUMMARY

The present disclosure attempts to provide a semiconductor device with improved reliability and/or productivity.

A semiconductor device according to at least one example embodiment includes a substrate; a bit line on the substrate, the bit line extending in a first horizontal direction; a plurality of word lines on the bit line, the plurality of word lines each extending in a second horizontal direction intersecting the first horizonal direction; a first active pattern and a second active pattern between the plurality of word lines such that the first active pattern and the second active pattern are spaced apart in the first horizontal direction; one or more cell capacitors, the one or more cell capacitors including at least one cell capacitor on at least one of the first active pattern or the second active pattern; and a plurality of shield patterns at a level between a level of the plurality of word lines and a level of the one or more cell capacitors, wherein each of the first active pattern and the second active pattern includes a first dopant region connected to the bit line, a second dopant region connected to the one or more cell capacitors, and a channel region that is between the first dopant region and the second dopant region, the plurality of shield patterns includes at least one of a shield pattern that overlaps the second dopant region of the first active pattern in the first horizontal direction or a shield pattern that overlaps the second dopant region of the second active pattern in the first horizontal direction, and the plurality of shield patterns includes at least one of a metal-containing material having an n-type work function or a polysilicon doped with an impurity.

A semiconductor device according to at least one example embodiment includes a substrate; a bit line that on the substrate, the bit line extending in a first horizontal direction; a plurality of word lines on the bit line, the plurality of word lines extending in a second horizontal direction intersecting the first horizontal direction; a first active pattern and a second active pattern between the plurality of word lines such that the first active pattern and the second active pattern are spaced apart in the first horizontal direction; a back gate electrode between the first active pattern and the second active pattern, the back gate electrode extending in the second horizontal direction; one or more storage contacts, the one or more storage contacts including at least one of a storage contact on the first active pattern or a storage contact on the second active pattern; one or more cell capacitors on the one or more storage contacts; and a plurality of shield patterns on at least one of the plurality of word lines and the back gate electrode, wherein each of the first active pattern and the second active pattern includes: a first dopant region connected to the bit line, a second dopant region connected to the storage contact, and a channel region between the first dopant region and the second dopant region, the plurality of shield patterns includes at least one of a shield pattern overlaps the second dopant region of the first active pattern in the first horizontal direction or a shield pattern that overlaps the second dopant region of the second active pattern in the first horizontal direction, and a work function of the plurality of shield patterns is less than or substantially equal to a work function of the second dopant region.

A semiconductor device according to at least one example embodiment includes a substrate; a bit line on the substrate, the substrate extending in a first horizontal direction; a plurality of word lines on the bit line, the plurality of word lines extending in a second horizontal direction intersecting the first horizontal direction; a plurality of active patterns positioned between the plurality of word lines such that the plurality of active patterns are spaced apart in the first horizontal direction, a back gate electrode between the plurality of active pattern, the back gate electrode extending in the second horizontal direction; at least one storage contact on the plurality of active pattern; at least one cell capacitor on the at least one storage contact; and a plurality of shield patterns, the plurality of shield patterns including a first shield pattern on the back gate electrode, and a second shield pattern on the plurality of word lines, wherein each of the plurality of active pattern includes a first dopant region connected to the bit line, a second dopant region connected to the storage contact, and a channel region between the first dopant region and the second dopant region, the plurality of shield patterns each overlap, in the first horizontal direction, the second dopant region of at least one corresponding active pattern of the plurality of active patterns, the first shield pattern and the second shield pattern include at least one of a metal-containing material having an n-type work function or a polysilicon doped with n-type impurity, a work function of each of the first shield pattern and the second shield pattern is lower than or substantially equal to a work function of the second dopant region of the corresponding active pattern, and the work function of each of the first shield pattern and the second shield pattern is greater than or substantially equal to a work function of the at least one storage contact.

A manufacturing method of a semiconductor device according to at least one example embodiment includes the steps of preparing a sub-substrate including a sequentially stacked buried insulating layer and an active layer, forming a back gate electrode extending in a first direction within the active layer, forming a first shield pattern on the back gate electrode, patterning the active layer to form a plurality of active patterns on both sides of the back gate electrode, forming a preliminary word line on the buried insulating layer on both sides of the back gate electrode, forming a second shield pattern on the preliminary word line, forming a storage contact connected to the plurality of active patterns, forming a cell capacitor on the storage contact, after removing the sub-substrate and the buried insulating layer, patterning the preliminary word line to form a plurality of word lines on both sides of the back gate electrode, forming a bit line extending in a second direction intersecting the first direction on the plurality of active patterns, forming a peripheral circuit structure on the substrate, and bonding the bit line and the peripheral circuit structure to face each other, and the first shield pattern and the second shield pattern includes polysilicon doped with an impurity or a metal-containing material having an n-type work function.

Each of the plurality of active patterns includes a first dopant region connected to the bit line, a second dopant region connected to the storage contact, and a channel region between the first dopant region and the second dopant region, and a work function of each of the first shield pattern and the second shield pattern may be lower than or substantially equal to a work function of the second dopant region.

The impurity may be an n-type impurity.

A concentration of the n-type impurity in each of the first shield pattern and the second shield pattern may be greater than or substantially equal to the concentration of the n-type impurity in the second dopant region.

The work functions of the first shield pattern and the second shield pattern may be greater than or substantially equal to a work function of the storage contact.

The metal-containing material having the n-type work function may include at least one of lanthanum (La), tantalum (Ta), tantalum nitride (TaN), niobium (Nb), or titanium nitride (TiN).

The manufacturing method of a semiconductor device may further include a step of forming a first shield insulating pattern on the back gate electrode before the step of forming the first shield pattern, a step of forming a first shield capping pattern on the first shield pattern, a step of forming a second shield insulating pattern on the preliminary word line before the step of forming the second shield pattern, and a step of forming a second shield capping pattern on the second shield pattern.

According to some example embodiments, since a shield pattern is formed such that it is positioned so as to overlap a dopant region of an active pattern which is connected to a capacitor, gate induced drain leakage current (GIDL) of the memory transistor may be reduced or suppressed.

### BRIEF DESCRIPTION OF THE DRAWINGS

FIG. 1 is a plan view of a semiconductor device according to at least one example embodiment.

FIG. 2 is a cross-sectional view illustrating a cross-section taken along lines A-A′ and B-B′ of FIG. 1.

FIG. 3 is a cross-sectional view illustrating a cross-section taken along line C-C′ of FIG. 1.

FIG. 4 is a partial enlarged view of region P1 of FIG. 3.

FIG. 5 to FIG. 11 are partial enlarged views illustrating cross-sections of semiconductor devices according to some example embodiments.

FIG. 12 is a cross-sectional view illustrating a cross-section of a semiconductor device according to some example embodiments.

FIG. 13 is an enlarged view of region R1 of FIG. 12.

FIG. 14 and FIG. 15 are partial enlarged views illustrating cross-sections of semiconductor devices according to some example embodiments.

FIG. 16 to FIG. 23 are cross-sectional views illustrating a manufacturing method of the semiconductor device according to at least one example embodiment.

### DETAILED DESCRIPTION

In the following detailed description, only certain embodiments have been shown and described, simply by way of illustration.

The present invention and concepts thereof may be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto. In the drawings, the thickness of layers, films, panels, regions, etc., are exaggerated for clarity. Further, in the drawings, for understanding and ease of description, the thickness of some layers and areas is exaggerated. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical and/or geometric values.

Further, it will be understood that when an element such as a layer, film, region, or substrate is referred to as being “on” another element, it may be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity. Additionally, it will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

In addition, in the entire specification, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

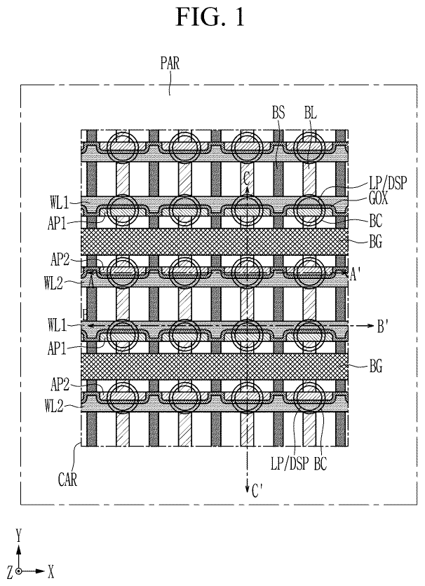

Hereinafter, a semiconductor device according to at least one example embodiment will be described below with reference to FIGS. 1 to 4.

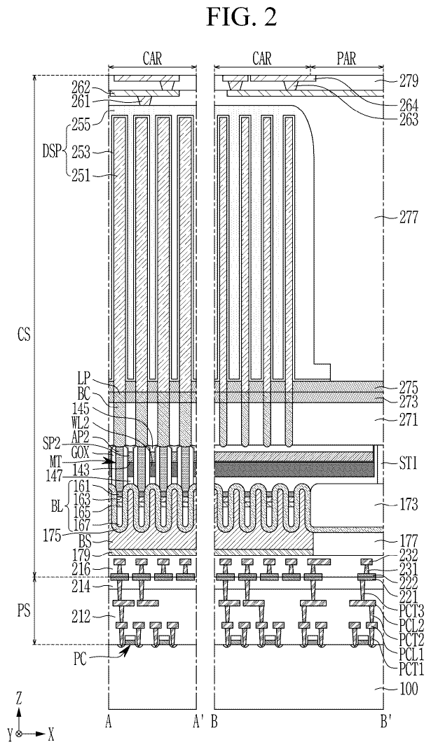

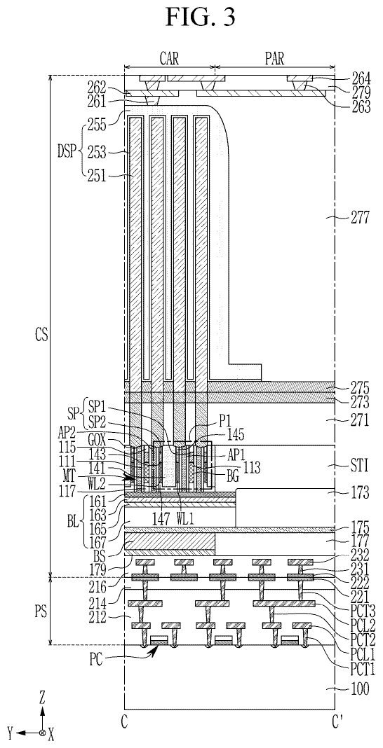

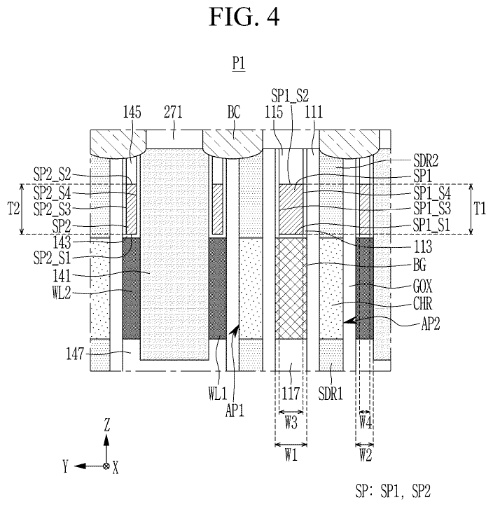

FIG. 1 is a plan view of a semiconductor device according to at least one example embodiment. FIG. 2 is a cross-sectional view illustrating a cross-section taken along lines A-A′ and B-B′ of FIG. 1. FIG. 3 is a cross-sectional view illustrating a cross-section taken along line C-C′ of FIG. 1. FIG. 4 is a partial enlarged view of region P1 of FIG. 3.

A semiconductor device according to at least one example embodiment may include a plurality of memory cells including vertical channel transistor (VCT). However, this is an example, and semiconductor devices according to embodiments are not limited thereto and may be variously changed.

Referring to FIGS. 1 to 4, the semiconductor device according to some example embodiments may include a substrate 100, and a peripheral circuit structure PS and a cell structure CS which are positioned on the substrate 100.

The substrate 100 may include a cell array region CAR, and a peripheral circuit region PAR defined around the cell array region CAR. For example, the peripheral circuit region PAR may be positioned adjacent to the cell array region CAR, and surround the cell array region CAR. However, the arrangement relationship of the cell array region CAR and the peripheral circuit region PAR is not limited thereto, and may be variously changed.

In the cell array region CAR, a plurality of memory cells which includes memory transistors MT and cell capacitors DSP, word lines WL and bit lines BL which are connected to them, and so on may be positioned, and in the peripheral circuit region PAR, a plurality of contacts (not shown in the drawings) and contact wiring lines (not shown in the drawings) connected to the components positioned in the cell array region CAR may be positioned.

A memory cell may include one memory transistor MT and one cell capacitor DSP. Depending on whether there is any charge stored in the cell capacitor DSP, two states distinguishable from each other may be determined, and thereby the cell capacitor DSP may function as a memory element.

A gate electrode of the memory transistor MT may be connected to a word line

WL, and a first source/drain electrode of the memory transistor MT may be connected to one terminal of the cell capacitor DSP, and a second source/drain electrode of the memory transistor MT may be connected to a bit line BL.

The substrate 100 may contain silicon, silicon germanium, indium antimonide, a lead tellurium compound, indium arsenide, indium phosphide, gallium arsenide, gallium antimonide, and/or a combination thereof, but is not limited thereto, and the material which is contained in the substrate 100 may be variously changed. For example, the substrate 100 may be a silicon substrate.

In at least one example embodiment, the peripheral circuit structure PS and the cell structure CS which are positioned on the substrate 100 may be positioned so as to overlap in a vertical direction. For example, the peripheral circuit structure PS and the cell structure CS may be sequentially stacked on the substrate 100. In other words, the cell structure CS may be positioned on the peripheral circuit structure PS. However, the present disclosure is not limited thereto, and the stacking relationship of the cell structure CS and the peripheral circuit structure PS may be variously changed. For example, the cell structure CS may be positioned adjacent to and side by side with the peripheral circuit structure PS in a horizontal direction. As another example, the cell structure CS may be positioned below the peripheral circuit structure PS so as to overlap the peripheral circuit structure in the vertical direction.

Hereinafter, the configuration and structure of the semiconductor device according to the example embodiments will be described in detail.

The example embodiments will be described on the assumption of the structure in which the cell structure CS is positioned on the peripheral circuit structure PS.

The peripheral circuit structure PS may be positioned on the substrate 100. The peripheral circuit structure PS may be positioned between the substrate 100 and the cell structure CS.

The peripheral circuit structure PS may be positioned throughout the cell array region CAR and peripheral circuit region PAR of the substrate 100. In other words, a portion of the peripheral circuit structure PS may be positioned on the cell array region CAR of the substrate 100, and the other portion may be positioned on the peripheral circuit region PAR.

Although not shown in the drawings, the peripheral circuit structure PS may include a core region and a peripheral region. The core region and the peripheral region may be collectively referred to as the logic region or the peripheral circuit region.

The core region may include a core bank, and the core bank may include core circuits such as a word line driver, a sense amplifier, a row decoder, a column decoder, and a read/write circuit (R/W circuit).

The peripheral region may include peripheral circuits such as a timing register, an address register, a data input register, a data output register, and a data input/output terminal.

The peripheral circuit structure PS may include a peripheral circuit PC for driving the components positioned in the cell structure CS. For example, the peripheral circuit PC may include the core circuits and/or the peripheral circuits mentioned above.

The peripheral circuit structure PS may include the peripheral circuit PC, peripheral circuit contacts PCT1, PCT2, and PCT3, peripheral circuit wiring lines PCL1 and PCL2, a peripheral circuit insulating layer 212, a first bonding insulating layer 214, and a plurality of first bonding pads 221.

The peripheral circuit PC may be positioned on the substrate 100. The peripheral circuit PC may be, for example, a sensing transistor, a transfer transistor, a driving transistor, etc. However, the type of the transistor of the peripheral circuit PC may be variously changed depending on the design of the semiconductor device. The peripheral circuit wiring lines PCL1 and PCL2 and/or the plurality of first bonding pads 221 may each include a conductive material, such as a metal, conductive oxide, and/or a conductive nitride. For example, the conductive material may be a zero-band gap material, a semiconductor doped to have a conductivity the same as or substantially similar to a zero-band gap material, a combination thereof, and/or the like.

The peripheral circuit insulating layer 212 may cover the peripheral circuit PC. In other words, the peripheral circuit insulating layer 212 may cover the side surfaces and upper surface of the peripheral circuit PC. The peripheral circuit insulating layer 212 may contain an insulating material. For example, the peripheral circuit insulating layer 212 may contain silicon oxide, silicon nitride, silicon oxynitride, and/or a low-dielectric constant material. However, the present disclosure is not limited thereto.

The peripheral circuit contacts PCT1, PCT2, and PCT3 and the peripheral circuit wiring lines PCL1 and PCL2 may be positioned in the peripheral circuit insulating layer 212.

The first peripheral circuit wiring line PCL1 may be connected to the peripheral circuit PC through the first peripheral circuit contact PCT1. The first peripheral circuit wiring line PCL1 may be connected to at least a source/drain region of the peripheral circuit PC positioned on one side, through the first peripheral circuit contact PCT1. The first peripheral circuit wiring line PCL1 and the second peripheral circuit wiring line PCL2 may be connected by the second peripheral circuit contact PCT2.

Although it is shown in the drawings that, in the at least one example embodiment, the peripheral circuit insulating layer 212 consists of a single layer, the present disclosure is not limited thereto, and the peripheral circuit insulating layer 212 may consist of multiple layers containing the same material and/or different materials.

When the peripheral circuit insulating layer 212 consists of multiple layers, at least some of the first peripheral circuit contact PCT1, the second peripheral circuit contact PCT2, the third peripheral circuit contact PCT3, the first peripheral circuit wiring line PCL1, the second peripheral circuit wiring line PCL2, and a third peripheral circuit wiring line PCL3 may be positioned in the same layer or in different layers.

The first bonding insulating layer 214 may be positioned on the peripheral circuit insulating layer 212.

The first bonding insulating layer 214 may contain an insulating material. For example, the first bonding insulating layer 214 may contain silicon carbonitride, but is not limited thereto. As another example, the first bonding insulating layer 214 may contain at least one of silicon oxide, silicon oxynitride, silicon carbon oxynitride, and silicon nitride.

The third peripheral circuit contact PCT3 may be positioned in the peripheral circuit insulating layer 212 and the first bonding insulating layer 214. In other words, a portion of the third peripheral circuit contact PCT3 may be positioned in the peripheral circuit insulating layer 212, and the other portion may be positioned in the first bonding insulating layer 214.

The plurality of first bonding pads 221 may be positioned in the first bonding insulating layer 214. The first bonding insulating layer 214 may surround the plurality of first bonding pads 221. The first bonding insulating layer 214 may surround the side surfaces and lower surfaces of the first bonding pads 221. The upper surface of the first bonding insulating layer 214 may be positioned substantially at the same level as that of the upper surfaces of the plurality of first bonding pads 221, and the first bonding insulating layer 214 may expose the upper surfaces of the plurality of first bonding pads 221. A first bonding pad 221 may be connected to the second peripheral circuit wiring line PCL2 through the third peripheral circuit contact PCT3.

In at least one example embodiment, the peripheral circuit structure PS and the cell structure CS may be bonded by a hybrid bonding process, such as a Cu-to-Cu (C2C) wafer bonding method, to form the semiconductor device. For example, the peripheral circuit structure PS and the cell structure CS may be bonded by a hybrid copper bonding (HCB) method to form the semiconductor device. However, the bonding method of the peripheral circuit structure PS and the cell structure CS is not limited thereto, and may be variously changed.

Although not shown in the drawings, in some example embodiments, the cell structure CS and the peripheral circuit structure PS may be connected in a direct bonding manner by the single through-hole via. For example, the cell structure CS and the peripheral circuit structure PS may be connected to a single through-via extending from the peripheral circuit structure PS to the cell structure CS.

Specifically, the peripheral circuit structure PS may include two surfaces facing each other. One surface of the two surfaces of the peripheral circuit structure PS may be a surface facing the cell structure CS, and the other surface of the peripheral circuit structure PS may be a surface facing the substrate 100.

Here, one surface of the peripheral circuit structure PS may refer to the front side of the peripheral circuit structure PS, and the other surface of the peripheral circuit structure PS may refer to the back side of the peripheral circuit structure PS.

Also, the cell structure CS may include one surface and another surface facing each other. One surface of the cell structure CS may be a surface facing the peripheral circuit structure PS, and another surface may be the opposite surface to one surface. Here, one surface of the cell structure CS may refer to the back side of the cell structure CS, and another surface of the cell structure CS may refer to the front side of the cell structure CS.

In at least one example embodiment, one surface of the peripheral circuit structure PS adjacent to the cell structure CS may be a bonding surface with the cell structure CS. Also, one surface of the cell structure CS adjacent to the peripheral circuit structure PS may be a bonding surface with the peripheral circuit structure PS. In other words, one surface of the peripheral circuit structure PS and one surface of the cell structure CS may be the bonding surfaces of the peripheral circuit structure PS and the cell structure CS. One surface of the peripheral circuit structure PS and one surface of the cell structure CS may constitute the interface of the peripheral circuit structure PS and the cell structure CS.

Specifically, the cell structure CS may include a second bonding insulating layer 216 which is in contact with the first bonding insulating layer 214 of the peripheral circuit structure PS. The second bonding insulating layer 216 may contain the same material as that of the first bonding insulating layer 214 which is positioned in the above-described peripheral circuit structure PS, and may be positioned on the first bonding insulating layer 214.

Inside the second bonding insulating layer 216 positioned in the cell structure CS, second bonding pads 222 may be positioned. The second bonding pads 222 may include a conductive material. The second bonding insulating layer 216 may surround the plurality of second bonding pads 222. The second bonding insulating layer 216 may surround the side surfaces and upper surfaces of the second bonding pads 222. The lower surface of the second bonding insulating layer 216 may be positioned substantially at the same level as that of the lower surfaces of the plurality of second bonding pads 222, and the second bonding insulating layer 216 may expose the lower surfaces of the plurality of second bonding pads 222.

The plurality of second bonding pads 222 which is positioned in the second bonding insulating layer 216 may form a metallic bond in a state where they are in direct contact with the plurality of first bonding pads 221 positioned in the first bonding insulating layer 214. The upper surfaces of the plurality of first bonding pads 221 and the lower surfaces of the plurality of second bonding pads 222 may be in contact. The plurality of first bonding pads 221 and the plurality of second bonding pads 222 may be positioned at the interface of the peripheral circuit structure PS and the cell structure CS, and may be in contact with each other.

Further, the first bonding insulating layer 214 which is positioned in the peripheral circuit structure PS and a plurality of second bonding insulating layers 216 which is positioned in the cell structure CS may be in contact with each other, thereby forming a junction insulating layer.

Accordingly, one surface of the cell structure CS and one surface of the peripheral circuit structure PS may be bonded. In other words, the plurality of first bonding pads 221 and the first bonding insulating layer 214 which are positioned in the peripheral circuit structure PS may constitute one surface or bonding surface of the peripheral circuit structure PS, and the plurality of second bonding pads 222 and the second bonding insulating layer 216 which are positioned in the cell structure CS may constitute one surface or bonding surface of the cell structure CS.

The first bonding pads 221 of the peripheral circuit structure PS and the second bonding pads 222 of the cell structure CS may be bonded to provide an electrical connection path between the peripheral circuit structure PS and the cell structure CS. For example, cell connection wiring lines 232 connected to the components included in the cell structure CS may be connected to the peripheral circuit PC and/or the peripheral circuit wiring lines PCL1 and PCL2 included in the peripheral circuit structure PS by the first bonding pads 221 and the second bonding pads 222.

The cell structure CS may include a cell connection wiring contact 231 and a cell connection wiring line 232 positioned in the second bonding insulating layer 216. The cell connection wiring contact 231 and the cell connection wiring line 232 may include a conductive material. The cell connection wiring line 232 may be connected to components positioned in the cell structure CS, and the cell connection wiring contact 231 may connect a second bonding pad 222 and the cell connection wiring line 232. For example, the cell connection wiring line 232 may be connected to the plurality of memory cells including the memory transistors MT and the cell capacitors DSP, the word line WL and the bit line BTL connected to the memory cells, and so on positioned in the cell structure CS.

Each of the peripheral circuit contacts PCT1, PCT2, and PCT3 and the peripheral circuit wiring lines PCL1 and PCL2 which are positioned in the peripheral circuit structure PS and the cell connection wiring contact 231 and the cell connection wiring line 232 which are positioned in the cell structure CS may contain a conductive material. For example, each may contain aluminum (Al), tungsten (W), titanium (Ti), copper (Cu), tantalum (Ta), etc. However, the present disclosure is not limited thereto.

In at least one example embodiment, a cell structure CS may include a plurality of bit lines BL, a plurality of word lines WL1 and WL2 that are positioned on the bit lines BL and extend across the plurality of bit lines BL, a plurality of active patterns AP1 and AP2 that are positioned between the word lines WL1 and WL2, a back gate electrode BG that is positioned between the active patterns AP1 and AP2 and extends across the plurality of bit lines BL, a storage contact BC that is positioned on the plurality of active patterns AP1 and AP2, a landing pad LP positioned on the storage contact BC, a cell capacitor DSP that is positioned on the landing pad LP, and a plurality of shield patterns SP that are positioned at a level between the word lines WL1 and WL2 and the cell capacitor DSP and overlaps at least a portion of the active patterns AP1 and AP2 in a horizontal direction.

The semiconductor device according to at least one example embodiment may include the plurality of bit lines BL.

The plurality of bit lines BL may extend in parallel with each other in a second direction Y that intersects a first direction X parallel to the substrate 100. The plurality of bit lines BL may be positioned on the substrate 100 so as to be spaced apart from each other in the first direction X.

In at least one example embodiment, the plurality of bit lines BL may extend in the second direction Y from a cell array region CAR to a peripheral circuit region PAR.

Accordingly, the end portions of the bit lines BL may be positioned in the peripheral circuit regions PAR positioned on both sides of the cell array region CAR in the second direction Y. The end portion of a bit line BL which is positioned in a peripheral circuit region PAR may be connected to a bit line contact (not shown in the drawings) that connects the bit line BL to a peripheral circuit structure PS.

The bit line BL may include a polysilicon layer 161, a first metal layer 163, a second metal layer 165, and a bit line capping layer 167.

The polysilicon layer 161 may contain polysilicon doped with an impurity, and the first metal layer 163 and the second metal layer 165 may contain a conductive material. For example, the first metal layer 163 may contain a conductive metal nitride (for example, titanium nitride, nitride tantalum, and the like), and the second metal layer 165 may contain a metal (for example, tungsten, titanium, tantalum, and the like).

Also, any one of the first metal layer 163 and the second metal layer 165 may contain metal silicide such as titanium silicide, cobalt silicide, or nickel silicide. However, the materials which are contained in the first metal layer 163 and the second metal layer 165 are not limited thereto, and may be variously changed.

The bit line capping layer 167 may contain an insulating material such as silicon nitride or silicon dioxide.

In some example embodiments, the bit lines BL may contain a two-dimensional or three-dimensional material, and may contain, for example, graphene which is a carbon-based two-dimensional material, carbon nanotube which is a three-dimensional material, or a combination thereof.

The plurality of bit lines BL may be positioned adjacent to the peripheral circuit structure PS. As the plurality of bit lines BL is positioned adjacent to the peripheral circuit structure PS, electrical connection paths between the bit lines BL and peripheral circuits PC may decrease.

The semiconductor device according to the at least one example embodiment may further include a bit line shield pattern BS and a spacer insulating layer 175 which are positioned between the peripheral circuit structure PS and the cell structure CS.

The bit line shield pattern BS may be positioned between the peripheral circuit structure PS and the bit line BL.

Further, the bit line shield pattern BS may be positioned between adjacent ones of the bit lines BL and may extend in the second direction Y.

In other words, the bit line shield pattern BS may be arranged alternately with the bit lines BL in the first direction X.

The spacer insulating layer 175 may be positioned conformally on the bit lines BL. The spacer insulating layer 175 may cover both side surfaces and the upper surface of each of the plurality of bit lines BL. The spacer insulating layer 175 may define and/or fill a gap region between the plurality of bit lines BL. The gap region of the spacer insulating layer 175 may extend in the second direction Y so as to be in parallel with the bit line BL.

The bit line shield pattern BS may contain a conductive material. For example, the bit line shield pattern BS may include metallic materials such as tungsten (W), titanium (Ti), nickel (Ni), and cobalt (Co). As another example, the bit line shield pattern BS may contain a conductive two-dimensional (2D) material such as graphene. However, the bit line shield pattern BS is not limited thereto.

The spacer insulating layer 175 may contain an insulating material. For example, the spacer insulating layer 175 may contain silicon oxide, silicon nitride, silicon oxynitride, and/or low-dielectric material.

The bit line shield pattern BS may be positioned on the spacer insulating layer 175. The bit line shield pattern BS may be positioned in the gap region of the spacer insulating layer 175.

As shown in FIG. 2 and FIG. 3, the bit line shield pattern BS may include line portions which are positioned between the bit lines BL adjacent to each other, and a connection portion that connects the line portions in common.

Specifically, the line portion of the bit line shield pattern BS may be positioned between bit lines BL and positioned in a plurality of gap regions defined by the spacer insulating layer 175. Accordingly, the line portions of the bit line shield pattern BS and the side surfaces of the bit lines BL may be spaced apart with the spacer insulating layer 175 interposed therebetween.

The connection portion of the bit line shield pattern BS may be connected to the line portions and integrated with the line portions. The connection portion of the bit line shield pattern BS may be positioned on the line portions so as to connect line portions, and positioned between the bit lines BL adjacent to each other. However, the present disclosure is not limited thereto, and in some example embodiments, the line portions and connection portions of the bit line shield pattern BS may be formed as separate components.

Although not shown, the connection portion of the bit line shield pattern BS may extend from the cell array region CAR to the peripheral circuit region PAR. Accordingly, the end portion of the connection portion of the bit line shield pattern BS may be positioned in the peripheral circuit region PAR. The connection portion of the bit line shield pattern BS which is positioned in the peripheral circuit region PAR may be connected to the bit line shield contact (not shown in the drawings).

The semiconductor device according to at least one example embodiment may further include a bit line shield capping layer 179 which is positioned on the bit line shield pattern BS, a first cell insulating layer 177 which is positioned between the spacer insulating layer 175 and a second bonding insulating layer 216, a second cell insulating layer 173 which is positioned on the spacer insulating layer 175, and an element isolation layer STI which is positioned on the second cell insulating layer 173.

The bit line shield capping layer 179 may be positioned between the bit line shield pattern BS and the second bonding insulating layer 216 so as to cover the bit line shield pattern BS.

The first cell insulating layer 177 may be positioned on the second bonding insulating layer 216. The upper surface of the first cell insulating layer 177 may be in contact with the spacer insulating layer 175, and a side surface of the first cell insulating layer 177 may be in contact with the end portion of the bit line shield pattern BS and an end portion of the bit line shield capping layer 179.

The second cell insulating layer 173 may be positioned on the spacer insulating layer 175.

As shown in FIG. 3, the second cell insulating layer 173 may be in contact with an end portion of the bit line BL, and cover the end portion of the bit line BL. However, this is an example, and the present disclosure is not limited thereto. For example, the second cell insulating layer 173 may be positioned apart from the end portion of the bit line BL.

The element isolation layer STI may be positioned on the second cell insulating layer 173. A portion of the element isolation layer STI may overlap with the bit line BL in the third direction Z, which is the vertical direction.

The bit line shield capping layer 179, the first cell insulating layer 177, the second cell insulating layer 173, and the element isolation layer STI may contain an insulating material, such as silicon oxide, silicon nitride, silicon oxynitride, and/or a low-dielectric material. For example, the bit line shield capping layer 179 may contain silicon nitride, and the first cell insulating layer 177, the second cell insulating layer 173, and the element isolation layer STI may contain silicon oxide. However, this is an example, and the materials which is contained in each of the bit line shield capping layer 179, the first cell insulating layer 177, the second cell insulating layer 173, and the element isolation layer STI may be variously changed.

The plurality of active patterns AP1 and AP2 may include a plurality of first active patterns AP1 and a plurality of second active patterns AP2, which are positioned spaced apart in the first direction X between the word lines WL1 and WL2. The plurality of first active patterns AP1 and the plurality of second active patterns AP2 may be positioned alternately in the second direction Y on the bit lines BL.

The first and second active patterns AP1 and AP2 may be arranged two-dimensionally on a plane along the first direction X and the second direction Y. In other words, the first active patterns AP1 and the second active patterns AP2 may be positioned so as to be spaced apart from and face each other in the second direction Y, respectively.

In at least one example embodiment, each of the first active patterns AP1 and the second active patterns AP2 may contain a semiconductor material, such as a monocrystalline semiconductor material. For example, the first active pattern AP1 and the second active pattern AP2 may contain monocrystalline silicon. However, the present disclosure is not limited thereto, and the materials which are contained in the first and second active patterns AP1 and AP2 may be variously changed. For example, the first and second active patterns AP1 and AP2 may contain at least one of polycrystalline semiconductors, oxide semiconductors, and two-dimensional materials. For example, the polycrystalline semiconductor may be polysilicon. As another example, the oxide semiconductor may be indium gallium zinc oxide (IGZO). As a further example, the two-dimensional material may be a semiconductive two-dimensional material such as at least one of MoS2, WS2, MoSe2, WSe2, and/or the like.

Each of the first active patterns AP1 and the second active patterns AP2 may have a length in the first direction X, have a width in the second direction Y, and have a height in the third direction Z. Each of the first active patterns AP1 and the second active patterns AP2 may include a first surface and a second surface facing each other in the third direction Z.

Here, the first surface may refer to the surface adjacent to the bit line BL, and the second surface may refer to the surface adjacent to the storage contact to be described below. In other words, the first surfaces of the active patterns AP1 and AP2 may correspond to the lower surfaces, and the second surfaces may correspond to the upper surfaces.

In at least one example embodiment, the first surface and second surface of each of the first active patterns AP1 and the second active patterns AP2 may have the same width or substantially similar widths. Further, the width of the first active patterns AP1 may be the same as (or substantially similar to) the width of the second active patterns AP2. However, the present disclosure is not limited thereto, and in some example embodiments, the first surface and second surface of each of the first active patterns AP1 and the second active patterns AP2 may have different widths. For example, the width of the second surface of each of the first active patterns AP1 and the second active patterns AP2 may be larger than the width of the first surface.

A detailed description of the first and second active patterns AP1 and AP2 will be made below with reference to FIG. 4.

A semiconductor device according to at least one example embodiment may include a plurality of back gate electrodes BG which extends in a different direction from that of the bit line BL, between the first active pattern AP1 and the second active pattern AP2.

The plurality of back gate electrodes BG may be positioned between the first active pattern AP1 and the second active pattern AP2, which are adjacent to each other in the second direction Y, and extend in the first direction X across the bit line BL. In other words, the plurality of back gate electrodes BG may extend across the bit lines BL in a direction different from the extension direction of the bit line BL.

The plurality of back gate electrodes BG may be positioned on bit lines BL and bit line shield patterns BS. On one side of the back gate electrode BG in the second direction Y, the first active pattern AP1 may be positioned, and on the other side of the back gate electrode BG in the second direction Y, the second active pattern AP2 may be positioned.

The thickness of the back gate electrodes BG in the third direction Z may be smaller than the thicknesses of the first and second active patterns AP1 and AP2 in the third direction Z. However, this is an example, and the relationship between the thickness of the back gate electrodes BG in the third direction Z and the thicknesses of the first and second active patterns AP1 and AP2 in the third direction Z may be variously changed.

Further, the back gate electrode BG may be positioned between a pair of first word line WL1 and second word line WL2 adjacent in the second direction Y. For example, the first active pattern AP1 may be positioned between the first word line WL1 to be described below and the back gate electrode BG, and the second active pattern AP2 may be positioned between the second word line WL2 to be described below and the back gate electrode BG. However, this is an example, and the arrangement relationship of the first and second active patterns AP1 and AP2, the first and second word lines WL1 and WL2 to be described below, and the back gate electrode BG is not limited thereto, and may be variously changed.

The back gate electrode BG may contain a conductive material. For example, the back gate electrode BG may contain at least one of doped polysilicon, conductive metal nitrides, conductive metal silicon nitrides, metal carbon nitrides, conductive metal silicides, conductive metal oxides, conductive two-dimensional materials, and metals. However, this is an example, and the conductive material may be variously changed.

During the operation of the semiconductor device, the back gate electrode BG may receive a negative voltage and raise the threshold voltage of a vertical channel transistor. In other words, as the vertical channel transistor is scaled down, the threshold voltage may decrease, whereby the leakage current characteristic may be protected from deterioration.

The semiconductor device according to the at least one example embodiment may further include a first back gate insulating pattern 111 and a second back gate insulating pattern 117.

The first back gate insulating pattern 111 and the second back gate insulating pattern 117 may be positioned between the first and second active patterns AP1 and AP2 adjacent to each other in the second direction Y. The first back gate insulating pattern 111 and the second back gate insulating pattern 117 may extend in the first direction X so as to be parallel with the back gate electrodes BG.

The first back gate insulating pattern 111 may be in contact with the first and second active patterns AP1 and AP2. The first back gate insulating pattern 111 may extend in the third direction Z along the side surfaces of each of the first and second active patterns AP1 and AP2 facing each other in the second direction Y.

The back gate electrode BG may include a first surface and a second surface facing each other in the third direction Z. Here, the first surface of the back gate electrode BG may refer to the surface facing a bit line BL and the bit line shield patterns BS, and the second surface of back gate electrode BG may refer to the surface facing a first shield pattern SP1 to be described below. In other words, the first surface of each back gate electrode BG may correspond to the lower surface of the back gate electrode BG, and the second surface may correspond to the upper surface of the back gate electrode BG.

The first back gate insulating pattern 111 may extend along both side surfaces of the back gate electrode BG, and the second back gate insulating pattern 117 may be positioned between the first surface of the back gate electrode BG and the bit line BL.

The first back gate insulating pattern 111 and the second back gate insulating pattern 117 may contain insulating materials. Each of the first back gate insulating pattern 111 and the second back gate insulating pattern 117 may contain an insulating material, such as at least one of silicon oxide, silicon oxynitride, or silicon nitride. However, the materials which are contained in the first back gate insulating pattern 111 and the second back gate insulating pattern 117 are not limited thereto, and may be variously changed.

The plurality of word lines WL1 and WL2 may be positioned on the bit lines BL and the shield pattern SP. The plurality of word lines WL1 and WL2 may include a plurality of first word lines WL1 and a plurality of second word lines WL2 which extend in the first direction X intersecting the second direction Y which is the extension direction of the bit lines

BL. The plurality of first word lines WL1 and second word lines WL2 may be positioned apart from each other in the second direction Y.

The first active pattern AP1 and the second active pattern AP2 may be positioned between the first word line WL1 and the second word line WL2 adjacent in the second direction Y.

The plurality of first word lines WL1 and the plurality of second word lines WL2 may overlap the bit line BL and the bit line shield pattern BS in the third direction Z. The plurality of first word lines WL1 and second word lines WL2 may extend in the third direction Z that intersects the first direction X and the second direction Y. The third direction Z may also be referred to as a vertical direction; in these cases, the first direction X and the second direction Y may also be referred to as a first horizontal direction X and a second horizontal direction Y, respectively.

In other words, the first word lines WL1 and the second word lines WL2 may be positioned between the bit lines BL and a second shield pattern SP2 to be described below, and extend in the third direction Z.

In at least one example embodiment, the word lines WL1 and WL2 may extend in the first direction X from the cell array region CAR to the peripheral circuit region PAR. Accordingly, the end portions of the word lines WL1 and WL2 may be positioned in the peripheral circuit region PAR, and the word line contact (not shown in the drawings) may be connected around the end portions of the word lines WL1 and WL2 positioned in the peripheral circuit region PAR.

In at least one example embodiment, the first and second word lines WL1 and WL2 have a rectangular shape in a cross-sectional view; however, the cross-sectional shape of the first and second word lines WL1 and WL2 is not limited thereto, and may be variously changed. For example, each of the first and second word lines WL1 and WL2 may have an ‘L’ shape in a cross-sectional view.

Each of the first and second word lines WL1 and WL2 may include a first surface and a second surface facing each other in the third direction Z. Here, the first surface of each of the first and second word lines WL1 and WL2 may refer to the surface facing the bit line BL and the bit line shield pattern BS, and the second surface may refer to the surface facing the second shield pattern SP2 to be described below. In other words, the first surface of each of the first and second word lines WL1 and WL2 may correspond to the lower surface, and the second surface may correspond to the upper surface.

The first and second word lines WL1 and WL2 may contain a conductive material.

For example, the first and second word lines WL1 and WL2 may contain at least one of doped polysilicon, conductive metal nitrides, conductive metal silicon nitrides, metal carbon nitrides, conductive metal silicides, conductive metal oxides, two-dimensional materials, and metals. However, the conductive material is not limited to this.

The semiconductor device according to the at least one example embodiment may further include a gate insulating pattern GOX that is positioned on the side surfaces of the word lines WL1 and WL2, a gate isolation pattern 141 that is positioned between the word lines WL1 and WL2, and a gate capping pattern 147 that is positioned on the first surfaces of the word lines WL1 and WL2.

The gate insulating pattern GOX may be in contact with the first and second active patterns AP1 and AP2. The gate insulating pattern GOX may extend in the third direction Z along the side surfaces of the first and second active patterns AP1 and AP2 facing each other in the second direction Y.

The gate isolation pattern 141 may be positioned between the first and second word lines WL1 and WL2 spaced apart in the second direction Y. The gate isolation pattern 141 may be positioned between the gate capping pattern 147 and a contact interlayer insulating layer 271 to be described below.

The gate isolation pattern 141 may be in contact with the first and second word lines WL1 and WL2. The first and second word lines WL1 and WL2 may be isolated and insulated by the gate isolation pattern 141. The gate isolation pattern 141 may extend in the third direction Z between the first and second word lines WL1 and WL2.

Specifically, the gate isolation pattern 141 may include a first surface and a second surface facing each other in the third direction Z. The first surface of the gate isolation pattern 141 may refer to the surface facing the gate capping pattern 147, and the second surface may refer to the surface facing the contact interlayer insulating layer 271. In other words, the first surface of the gate isolation pattern 141 may correspond to the lower surface, and the second surface may correspond to the upper surface.

The thickness of the gate isolation pattern 141 in the third direction Z may be larger than the thickness of the first and second word lines WL1 and WL2 in the third direction Z. The first surface of the gate isolation pattern 141 may be positioned at a lower level than the first surface of the first and second word lines WL1 and WL2, and the second surface of the gate isolation pattern 141 may be positioned at a higher level than the second surface of the first and second word lines WL1 and WL2.

The gate capping pattern 147 may be positioned on the first surfaces of the word lines WL1 and WL2. The gate capping pattern 147 may cover the first surfaces of the word lines WL1 and WL2.

The first surface of the gate isolation pattern 141 and the side surfaces adjacent thereto may be covered by the gate capping pattern 147, and the second surface may be covered by the contact interlayer insulating layer 271.

The gate insulating pattern GOX may contain an insulating material, such as at least one of silicon oxide, silicon oxynitride, a high-dielectric constant material having a dielectric constant higher than that of silicon oxide, or a combination thereof. For example, the high-dielectric constant material may contain any one of HfO₂, HfSiO, HfSiON, HfTaO, HfTiO, HfZrO, ZrO₂, Al₂O₃, or combinations thereof, but is not limited thereto.

The gate isolation pattern 141 and the gate capping pattern 147 may contain an insulating material, such as at least one of silicon oxide, silicon nitride, or combinations thereof. For example, the gate isolation pattern 141 may contain silicon oxide, and the gate capping pattern 147 may contain silicon nitride. However, the present disclosure is not limited thereto.

The plurality of shield patterns SP may overlap at least some of the first and second active patterns AP1 and AP2 in the second direction Y which is a horizontal direction. The plurality of shield patterns SP may overlap at least a portion of one of the first and second active patterns AP1 and AP2 in a direction parallel to extension direction of the bit line BL. In other words, the plurality of shield patterns SP may overlap at least the portion one of the first and second active patterns AP1 and AP2 in a direction that vertically intersects the extension direction of the word lines WL1 and WL2.

The plurality of shield patterns SP may be positioned at a level between the word lines WL1 and WL2 and the cell capacitor DSP and/or between the back gate electrode BG and the cell capacitor DSP.

The plurality of shield patterns SP may be positioned at a level between the upper surfaces of the word lines WL1 and WL2 and the lower surface of the storage contact BC to be described below and/or between the upper surface of the back gate electrode BG and the lower surface of the storage contact BC.

The plurality of shield patterns SP may be positioned on at least one of the plurality of word lines WL1 and WL2 and the plurality of back gate electrodes BG. In other words, the plurality of shield patterns SP may be positioned to overlap at least one of the plurality of word lines WL1 and WL2 and the plurality of back gate electrodes BG in the third direction Z.

In at least one example embodiment, the plurality of shield patterns SP may include a plurality first shield patterns SP1 which is positioned on the back gate electrode BG, and a plurality of second shield pattern SP2 which is positioned on the word lines WL1 and WL2.

The plurality of first shield pattern SP1 may be positioned so as to overlap at least a portion of each of the plurality of back gate electrodes BG in the third direction Z, and a plurality of second shield pattern SP2 may be positioned so as to overlap at least a portion of each of the plurality of word lines WL1 and WL2 in the third direction Z.

The first shield pattern SP1 may extend in the third direction Z on the back gate electrode BG, and the second shield pattern SP2 may extend in the third direction Z on the word lines WL1 and WL2.

The plurality of shield patterns SP may be positioned between the first active pattern AP1 and the second active pattern AP2 adjacent to each other in the second direction Y. The thickness of the plurality of shield patterns SP in the third direction Z may be smaller than the thickness of the first and second active patterns AP1 and AP2 in the third direction Z.

Accordingly, each shield patterns SP may be positioned so as to overlap some portions of the first and second active patterns AP1 and AP2 in the second direction Y. However, the arrangement of the plurality of patterns SP is not limited thereto and may be variously changed.

A detailed description of the arrangement relationship of the first and second active patterns AP1 and AP2 and the plurality of shield patterns SP will be made below with reference to FIG. 4.

Although not shown in detail FIG. 1, In at least one example embodiment, the first shield pattern SP1 may have the same (or a substantially similar) shape as that of the back gate electrode BG in a plan view, and the second shield pattern SP2 may have the same (or a substantially similar) shape as that of each of the first word line WL1 and the second word line WL2 in a plan view. However, but the present disclosure is not limited thereto. For example, the first shield pattern SP1 and the back gate electrode BG may have a different shape in a plan view, and the second shield pattern SP2 and each of the words lines WL1 and WL2 may have the same (or a substantially) shape in a plan view. As another example, the first shield pattern SP1 and the back gate electrode BG may have the same (or a substantially) shape in a plan view, and the second shield pattern SP2 and each of the words lines WL1 and WL2 may have different shapes in a plan view. As another example, the first shield pattern SP1 and the back gate electrode BG may have a different shape in a plan view, and the second shield pattern SP2 and each of the words lines WL1 and WL2 may have a different shape in a plan view.

The semiconductor device according to the at least one example embodiment may further include a first shield insulating pattern 113 that is positioned between the back gate electrode BG and the first shield pattern SP1, a first shield capping pattern 115 that is positioned on the first shield pattern SP1, a second shield insulating pattern 143 that is positioned between the word lines WL1 and WL2 and the second shield pattern SP2, and a second shield capping pattern 145 that is positioned on the second shield pattern SP2.

The first shield insulating pattern 113 may be positioned between the back gate electrode BG and the first shield pattern SP1, and isolate and insulate them. The first shield capping pattern 115 may be positioned on the first shield pattern SP1, and cover the first shield pattern SP1. The first shield capping pattern 115 may be positioned between the first shield pattern SP1 and the contact interlayer insulating layer 271 to be described below.

The first shield insulating pattern 113 may extend along the side surface of the first shield pattern SP1 and side surfaces of the first shield capping pattern 115. Both side surfaces of the first shield insulating pattern 113 may be surrounded by the first back gate insulating pattern 111.

The first shield insulating pattern 113 may be positioned between the first shield pattern SP1 and the first back gate insulating pattern 111, and between the first shield capping pattern 115 and the first back gate insulating pattern 111.

The second shield insulating pattern 143 may be positioned between the word lines WL1 and WL2 and the second shield pattern SP2, and isolate and insulate them. The second shield capping pattern 145 may be positioned on the second shield pattern SP2 and cover the second shield pattern SP2. The second shield capping pattern 145 may be positioned between the second shield pattern SP2 and the storage contact BC to be described below.

The second shield insulating pattern 143 may extend along the side surface of the second shield pattern SP2 and side surfaces of the second shield capping pattern 145. Both side surfaces of the second shield capping pattern 145 may be surrounded by a gate insulating pattern GOX.

The second shield insulating pattern 143 may be positioned between the second shield pattern SP2 and the gate insulating pattern GOX, and between the second shield capping pattern 145 and the gate insulating pattern GOX.

Each of the first shield insulating pattern 113, the first shield capping pattern 115, the second shield insulating pattern 143, and the second shield capping pattern 145 may contain an insulating material. For example, the insulating material may contain silicon oxide, silicon nitride, silicon oxynitride, etc., but is not limited thereto, and may be variously changed.

In at least one example embodiment, the plurality of shield patterns SP may be configured such that no voltage is applied directly to the plurality of shield patterns SP. In other words, the plurality of shield patterns SP may be electrically floating.

In some example embodiments, a voltage may be applied to the plurality of shield patterns SP. For example, the same voltage may be applied to the back gate electrode BG and the first shield pattern SP1, and the same voltage may be applied to the word lines WL1 and WL2 and the second shield pattern SP2. As another example, different voltages may be applied to the back gate electrode BG and the first shield pattern SP1, and the same voltage may be applied to the word lines WL1 and WL2 and the second shield pattern SP2. As another example, the same voltage may be applied to the back gate electrode BG and the first shield pattern SP1, and different voltages may be applied to the word lines WL1 and WL2 and the second shield pattern SP2. As another example, different voltages may be applied to the back gate electrode BG and the first shield pattern SP1, and different voltages may be applied to the word lines WL1 and WL2 and the second shield pattern SP2.

As such, when a voltage is applied to the plurality of shield patterns SP, the plurality of shield patterns SP may function as gate electrodes of the memory transistor MT together with the plurality of word lines WL1, and WL2 and/or the back gate electrode BG, thereby controlling the threshold voltage of the memory transistor MT.

The semiconductor device according to the at least one example embodiment may further include the contact interlayer insulating layer 271, a pad isolation insulating layer 273, and a contact etch stop layer 275 sequentially stacked on the active patterns AP1 and AP2.

The contact interlayer insulating layer 271 may be positioned on the active patterns AP1 and AP2. The contact interlayer insulating layer 271 may cover the first back gate insulating pattern 111, the first and second shield capping patterns 115 and 145, the gate isolation pattern 141, and the element isolation layer STI.

The contact interlayer insulating layer 271, the pad isolation insulating layer 273, and the contact etch stop layer 275 each including an insulating material, for example at least one of silicon oxide, silicon nitride, or a combination thereof. For example, the contact interlayer insulating layer 271 may contain silicon oxide, and the pad isolation insulating layer 273 and the contact etch stop layer 275 may contain silicon nitride. However, the present disclosure is not limited thereto.

In the cell array region CAR of the cell structure CS, the storage contact BC, the landing pad LP, and the cell capacitor DSP may be sequentially stacked.

The semiconductor device according to the at least one example embodiment may include a plurality of the storage contacts BC. The plurality of storage contacts BC may pass through the contact interlayer insulating layer 271. The plurality of storage contacts BC may be connected to the first and second active patterns AP1 and AP2, respectively. The storage contacts BC adjacent to each other may be isolated and insulated from each other by the contact interlayer insulating layer 271.

The plurality of storage contacts BC may be arranged in a matrix pattern along the first direction X and the second direction Y on a plane (e.g., a horizonal plane). In FIG. 1, it is shown that each storage contact BC has a circular shape on a plane, however, the present disclosure is not limited thereto, and each storage contact BC may have various shapes such as an oval shape, a rectangular shape, a square shape, a rhombic shape, a hexagonal shape, and/or the like in a plan view.

The storage contact BC may contain a conductive material. For example, the conductive material may contain at least one of impurity-doped polysilicon, a conductive metal nitride, a conductive metal silicon nitride, a metal nitride, a conductive metal silicide, a conductive metal oxide, a two-dimensional material, and a metal. As a more specific example, the storage contact BC may contain polysilicon doped with n-type impurity. However, the material contained in the storage contact BC is not limited thereto, and may be variously changed.

The semiconductor device according to the at least one example embodiment may include a plurality of landing pads LP. The plurality of landing pads LP may be positioned on the plurality of storage contacts BC, respectively.

The plurality of landing pads LP may be arranged in a matrix form along the first direction X and the second direction Y in a plan view. In FIG. 1, it is shown that each landing pad LP has a circular shape on a plane, however, the present disclosure is not limited thereto, and each landing pad LP may have various shapes such as an oval shape, a rectangular shape, a square shape, a rhombic shape, a hexagonal shape, and/or the like, in a plan view.

Between the landing pads LP, the pad isolation insulating layers 273 may be positioned. The upper surface of the landing pad LP may be positioned at the same (or substantially similar) level as that of the upper surface of the pad isolation insulating layer 273.

The landing pad LP may contain a conductive material. The conductive material may contain, for example, at least one of doped polysilicon, conductive metal nitrides, conductive metal silicon nitrides, metal carbonitrides, conductive metal silicides, conductive metal oxides, two-dimensional materials, metals, a combination thereof, and/or the like.

The semiconductor device according to the at least one example embodiment may include a plurality of cell capacitors DSP. The plurality of cell capacitors DSP may be arranged in a matrix pattern along the first direction X and the second direction Y, as shown in FIG. 1.

The plurality of cell capacitors DSP may be positioned on the plurality of landing pads LP, respectively. The plurality of cell capacitors DSP may entirely or partially overlap the plurality of landing pads LP in the third direction Z, respectively. The plurality of cell capacitors DSP may be connected to the first and second active patterns AP1 and AP2, respectively.

Each cell capacitor DSP may include a first electrode 251, a second electrode 255, and a dielectric film 253 which is positioned between the first electrode 251 and the second electrode 255.

The first electrode 251 may pass through the contact etch stop layer 275 and be connected to the landing pad LP. The first electrode 251 may extend in the third direction Z on the landing pad LP.

The first electrode 251 may contain a conductive material, such as a metal, a conductive metal nitride, or a combination thereof. For example, the first electrode 251 may contain at least one of TiN, Ru, TaN, WN, Pt, Ir, a combination thereof, and/or the like. However, the material which is contained in the first electrode 251 is not limited thereto, and may be variously changed.

The dielectric film 253 may extend so as to conform to the profile of the upper surface and side surfaces of the first electrode 251. In other words, the dielectric film 253 may cover the side surfaces and upper surface of the first electrode 251. A portion of the dielectric film 253 may be positioned on the upper surface of the contact etch stop layer 275. In other words, a portion of the dielectric film 253 may be positioned between the contact etch stop layer 275 and the second electrode 255.

The dielectric film 253 may contain a dielectric material, such as at least one of tantalum oxide (Ta₂O₅), aluminum oxide (Al₂O₃), titanium oxide (TiO₂), or a combination thereof. However, the present disclosure is not limited thereto, and the material which is contained in the dielectric film 253 may be variously changed.

The second electrode 255 may be positioned on the dielectric film 253. The second electrode 255 may entirely cover the first electrode 251 and the dielectric film 253 may electrically insulate the second electrode 255 from the first electrode 251. In other words, the second electrode 255 may cover the upper surface and side surfaces of the first electrode 251.

The second electrode 255 may contain a conductive material, such as a metal material. For in at least some embodiments, the second electrode 255 may include at least one of W, Ti, Ru, SiGe, etc. For example, the second electrode 255 may contain tungsten (W). However, the material which is contained in the second electrode 255 is not limited thereto, and may be variously changed. For example, the second electrode 255 may contain conductive metal nitride, metal silicide, or a combination thereof.

The semiconductor device according to the at least one example embodiment may further include a third cell insulating layer 277 and a fourth cell insulating layer 279 sequentially stacked on the contact etch stop layer 275.

Also, the semiconductor device according to the at least one example embodiment may further include a first cell wiring contact 261 and a first cell wiring line 262 which are positioned in the third cell insulating layer 277, and a second cell wiring contact 263 and a second cell wiring line 264 which are positioned in the fourth cell insulating layer 279.

The third cell insulating layer 277 may entirely cover the cell capacitor DSP. In other words, the third cell insulating layer 277 may cover the upper surface and side surfaces of the cell capacitor DSP.

The cell capacitor DSP may be connected to the first cell wiring line 262 through the first cell wiring contact 261, and the first cell wiring line 262 may be connected to the second cell wiring line 264 through the second cell wiring contact 263.

In at least one example embodiment, the first cell wiring line 262 may be a wiring line to which an external voltage is applied, or a redistribution layer (RDL) connected to a wiring line to which a voltage is applied. At least a portion of the second cell wiring line 264 may correspond to a power line to which an external voltage is applied. However, this is an example, and the functions of the first cell wiring line 262 and the second cell wiring line 264 may be variously changed.

The first cell wiring contact 261, the first cell wiring line 262, the second cell wiring contact 263, and the second cell wiring line 264 may contain a conductive material, such as a metal material. For example, the first cell wiring contact 261, the first cell wiring line 262, the second cell wiring contact 263, and the second cell wiring line 264 may each contain at least one of copper (Cu), aluminum (Al), tungsten (W), titanium (Ti), and tantalum (Ta), combinations thereof, and/or the like. Hereinafter, the plurality of shield patterns SP will be described in detail with reference to FIG. 3 and FIG. 4.

Referring to FIG. 4 together with FIG. 3, each of the first and second active patterns AP1 and AP2 may include a first dopant region SDR1 connected to the bit line BL, a second dopant region SDR2 connected to the cell capacitor DSP, and a channel region CHR that is positioned between the first and second dopant regions SDR1 and SDR2.

The second dopant region SDR2 may be connected to the cell capacitor DSP through the storage contact BC and the landing pad LP. In other words, the second dopant region SDR2 may be directly connected to the storage contact BC.

The first and second dopant regions SDR1 and SDR2 are regions inside the first and second active patterns AP1 and AP2, doped with an impurity, and a concentration of impurity in the first and second dopant regions SDR1 and SDR2 may be greater than a concentration of impurity in the channel region CHR.

The first and second active patterns AP1 and AP2 may be controlled by the word lines WL1 and WL2 to be described below and/or the back gate electrodes BG during the operation of the semiconductor device. As described above, in at least one example embodiment, when the first and second active patterns AP1 and AP2 contain a monocrystalline semiconductor material, the leakage current characteristic of the semiconductor memory device may be improved.

The first and second dopant regions SDR1 and SDR2 of the active patterns AP1 and AP2 may correspond to the first source/drain electrode and second source/drain electrode of the memory transistor MT, and the channel region CHR may correspond to the channel of the memory transistor MT.

In at least one example embodiment, the thickness of the word lines WL1 and WL2 in the third direction Z may be the same as (or substantially similar to) the thickness of the back gate electrode BG in the third direction Z. In other words, the upper surfaces and lower surfaces of the word lines WL1 and WL2 may be positioned at the same (or a substantially similar) levels as those of the upper surface and lower surface of the back gate electrode BG, respectively. However, the present disclosure is not limited thereto, and either or both of the upper surfaces and lower surfaces of the word lines WL1 and WL2 may be positioned at levels different from those of the upper surface and lower surface of the back gate electrode BG.

Further, in some example embodiments, the thickness of the first and second word lines WL1 and WL2 in the third direction Z may be smaller than the thickness of the first and second active patterns AP1 and AP2 in the third direction Z. However, the relationship of the thickness of the word lines WL1 and WL2 in the third direction Z and the thickness of the back gate electrode BG in the third direction Z, the arrangement relationship of the word lines WL1 and WL2 and the back gate electrode BG, and the relationship of the thickness of the word lines WL1 and WL2 in the third direction Z and the thickness of the active patterns AP1 and

AP2 in the third direction Z are not limited thereto, and may be variously changed.

In at least one example embodiment, the shield patterns SP may overlap at least one second dopant region SDR2 of the active patterns AP1 and AP2 in the second direction Y which is a horizontal direction. Further, the shield patterns SP may be positioned at a higher level than the channel region CHR so as not to overlap the channel region CHR in the second direction Y.

The thickness of the shield patterns SP in the third direction Z may be smaller than the thickness of the second dopant region SDR2 in the third direction Z. Accordingly, the shield patterns SP may overlap a portion of the second dopant region SDR2 in the second direction Y. In other words, the shield patterns SP may overlap the second dopant region SDR2 in a direction intersecting the extension direction of the second dopant region SDR2 of each of the active patterns AP1 and AP2.

The first shield pattern SP1 may include a first surface SP1_S1 and a second surface SP1_S2 which face each other in the third direction Z. The first surface SP1_S1 of the first shield pattern SP1 may be in contact with the first shield insulating pattern 113, and the second surface SP1_S2 may be in contact with the first shield capping pattern 115.

The first shield insulating pattern 113 may surround the first surface SP1_S1 of the first shield pattern SP1, and a first side surface SP1_S3 and a second side surface SP1_S4 of the first shield pattern SP1 which face each other in the second direction Y.

The first shield insulating pattern 113 may extend conformally along the first surface SP1_S1, the first side surface SP1_S3, and the second side surface SP1_S4 of the first shield pattern SP1. In other words, the first shield insulating pattern 113 may extend along the first surface SP1_S1, the first side surface SP1_S3, and the second side surface SP1_S4 of the first shield pattern SP1 with substantially the same thickness. However, the present disclosure is not limited thereto, and the thickness of the first shield insulating pattern 113 positioned on the first surface SP1_S1 of the first shield pattern SP1 may be different from the thickness of the first shield insulating pattern 113 positioned on the first side surface SP1_S3 and the second side surface SP1_S4 of the first shield pattern SP1.

The upper surface of the first shield insulating pattern 113 may be positioned at substantially the same level as the upper surface of the first back gate insulating pattern 111 and the upper surface of the first shield capping pattern 115. The upper surface of the first shield insulating pattern 113 may be in contact with the contact interlayer insulating layer 271.

The second shield pattern SP2 may include a first surface SP2_S1 and a second surface SP2_S2 which face each other in the third direction Z. The first surface SP2_S1 of the second shield pattern SP2 may be in contact with the second shield insulating pattern 143, and the second side surface SP2_S2 may be in contact with the second shield capping pattern 145.

Here, the first surface SP1_S1 of the first shield pattern SP1 may correspond to the lower surface, and the second surface SP1_S2 may correspond to the upper surface. Further, the first surface SP2_S1 of the second shield pattern SP2 may correspond to lower surface, and the second surface SP2_S2 may correspond to the upper surface.

The second shield insulating pattern 143 may surround the first surface SP2_S1 of the second shield pattern SP2, and the first side surface SP2_S3 and the second side surface SP2_S4 of the second shield pattern SP2 which face each other in the second direction Y.

The second shield insulating pattern 143 may extend conformally along the first surface SP2_S1, the first side surface SP2_S3, and the second side surface SP2_S4 of the second shield pattern SP2. In other words, the second shield insulating pattern 143 may extend along the first surface SP2_S1, the first side surface SP2_S3, and the second side surface SP2_S4 of the second shield pattern SP2 with substantially the same thickness. However, the present disclosure is not limited thereto, and the thickness of the second shield insulating pattern 143 positioned on the first surface SP2_S1 of the second shield pattern SP2 may be different from the thickness of the second shield insulating pattern 143 positioned on the first side surface SP2_S3 and the second side surface SP2_S4 of the second shield pattern SP2.

The upper surface of the second shield insulating pattern 143 may be in contact with the storage contact BC. A portion of the second shield capping pattern 145 may be recessed by the storage contact BC. In other words, the upper surface of the second shield capping pattern 145 may be recessed by the storage contact BC and include a curved surface. The upper surface of the second shield capping pattern 145 may be positioned at a lower level than the upper surface of the gate isolation pattern 141.

The first shield insulating pattern 113 and the second shield insulating pattern 143 may surround the first shield pattern SP1 and the second shield pattern SP2, respectively, with a same (or substantially similar) thickness.

Specifically, the thickness of the first shield insulating pattern 113 in the third direction Z positioned on the first surface SP1_S1 of the first shield pattern SP1 and the thickness of the second shield insulating pattern 143 in the third direction Z positioned on the first surface SP2_S1 of the second shield pattern SP2 may be substantially the same.

Further, the thickness of the first shield insulating pattern 113 positioned on both side surfaces SP1_S3, SP1_S4 of the first shield pattern SP1 in the second direction Y may be the same as (or substantially similar to) the thickness of the second shield insulating pattern 143 positioned on both side surfaces SP2_S3, SP2_S4 of the second shield pattern SP2 in the second direction Y. However, the present disclosure is not limited thereto, and the first shield insulating pattern 113 and the second shield insulating pattern 143 may surround the first shield pattern SP1 and the second shield pattern SP2, respectively, with different thicknesses.

Among the plurality of second shield patterns SP2, the first side surface SP2_S3 of a second shield pattern SP2 positioned on the word lines WL1 and WL2 may face the gate isolation pattern 141 with the second shield insulating pattern 143 interposed therebetween, and the second side surface SP2_S4 may face the gate insulating pattern GOX with the second shield insulating pattern 143 interposed therebetween.

In at least one example embodiment, the back gate electrode BG may have a first width W1, and the word lines WL1 and WL2 may have a second width W2. The first shield pattern SP1 may have a third width W3, and the second shield pattern SP2 may have a fourth width W4.

Further, the first shield capping pattern 115 positioned on the first shield pattern SP1 may have the third width W3, and the second shield capping pattern 145 positioned on the second shield pattern SP2 may have the fourth width W4. In other words, the first shield capping pattern 115 may have the width the same as (or substantially similar to) that of the first shield pattern SP1, and the second shield capping pattern 145 may have the width the same as (or substantially similar to) that of the second shield pattern SP2.

Here, the first width W1, the second width W2, the third width W3, and the fourth width W4 may each refer to the width in the second direction Y.

In at least one example embodiment, the first width W1 may be greater than the second width W2, the third width W3, and the fourth width W4. In other words, the width of the back gate electrode BG may be larger than the width of the first shield pattern SP1, the width of each of word lines WL1 and WL2, and the width of the second shield pattern SP2.

The second width W2 may be smaller than the first width W1 and the third width W3, and larger than the fourth width W4. In other words, the width of each of word lines WL1 and WL2 may be smaller than the width of the back gate electrode BG and the width of the first shield pattern SP1, and larger than the width of the second shield pattern SP2.

The third width W3 may be smaller than the first width W1 and larger than the second width W2 and the fourth width W4. In other words, the width of the first shield pattern SP1 may be smaller than the width of the back gate electrode BG, and larger than the widths of each of the word lines WL1 and WL2 and the width of the second shield pattern SP2.

The fourth width W4 may be smaller than the first width W1, the second width W2, and the third width W3. In other words, the width of the second shield pattern SP2 may be smaller than the widths of the back gate electrode BG, the first shield pattern SP1, and word lines WL1, and WL2, respectively. However, the present disclosure is not limited thereto, the relationship between the first width W1, the second width W2, the third width W3, and the fourth width W4 may be variously changed.

In some example embodiments, the first width W1 and the second width W2 may be the same or substantially similar. In other words, the width of the back gate electrode BG may be the same as (or substantially similar to) the width of each of word lines WL1 and WL2.

In these cases, the third width W3 of the first shield pattern SP1 and the fourth width W4 of the second shield pattern SP2, which are positioned on the back gate electrode BG and word lines WL1 and WL2, respectively, may be substantially the same.

In some example embodiments, when the first shield insulating pattern 113 positioned on both side surfaces SP1_S3, SP1_S4 of the first shield pattern SP1 is omitted, the first width W1 and the third width W3 may be substantially the same. In other words, when the first shield insulating pattern 113 positioned on both sides surfaces SP1_S3, SP1_S4 of the first shield pattern SP1 is omitted, the width of the back gate electrode BG and the width of the first shield pattern SP1 may be substantially the same.

Further, when the second shield insulating pattern 143 positioned on both sides surfaces SP1_S3, SP1_S4 of the second shield pattern SP2 is omitted, the second width W2 and the fourth width W4 may be substantially the same. In other words, when the second shield insulating pattern 143 positioned on both sides surfaces SP1_S3, SP1_S4 of the second shield pattern SP2 is omitted, the widths of each of the word lines WL1 and WL2 and the width of the second shield pattern SP2 may be substantially the same.

In at least one example embodiment, the first shield pattern SP1 may have a first thickness T1, and the second shield pattern SP2 may have a second thickness T2.

Here, the first thickness T1 may refer to the thickness in the third direction Z between the first surface SP1_S1 and the second surface SP1_S2 of the first shield pattern SP1, and the second thickness T2 may refer to the thickness in the third direction Z between the first surface SP2_S1 and the second surface SP2_S2 of the second shield pattern SP2.

In at least one example embodiment, the first thickness T1 may be the same as (or substantially similar to) the second thickness T2. In other words, the thickness of the first shield pattern SP1 may be the same as (or substantially similar to) the thickness of the second shield pattern SP2. However, the present disclosure is not limited thereto, and the relationship between first thickness T1 and second thickness T2 may be variously changed.

In at least one example embodiment, the first surface SP1_S1 of the first shield pattern SP1 may be positioned at substantially the same level as the first surface SP2_S1 of the second shield pattern SP2. Further, the second surface SP1_S2 of the first shield pattern SP1 may be positioned at substantially the same level as the second surface SP2_S2 of the second shield pattern SP2. However, the present disclosure is not limited thereto, the arrangement relationship between the first shield pattern SP1 and the second shield pattern SP2 may be variously changed.

In some example embodiments, a thickness in the third direction Z of the first shield insulating pattern 113 positioned on the first surface SP1_S1 of the first shield pattern SP1 may be different from a thickness in the third direction Z of the second shield insulating pattern 143 positioned on the first surface SP2_S1 of the second shield pattern SP2, or the first thickness T1 of the first shield pattern SP1 may be different from a second thickness T2 of the second shield pattern SP2.

Accordingly, the level relationship between the first surface SP1_S1 of the first shield pattern SP1 and the first surface SP2_S1 of the second shield pattern SP2 and/or the level relationship between the second surface SP1_S2 of the first shield pattern SP1 and the second surface SP2_S2 of the second shield pattern SP2 may be variously changed.

In at least one example embodiment, a work function of the shield pattern SP may be lower than or substantially equal to a work function of the second dopant region SDR2 of each of the active patterns AP1 and AP2. In other words, the work function of the shield pattern SP may be substantially the same as or less than the work function of the second dopant region SDR2 of each of the active patterns AP1 and AP2.

Further, the work function of the shield pattern SP may be greater than or substantially equal to the work function of the storage contact BC. In other words, the work function of the shield pattern SP may be substantially the same as or greater than the work function of the storage contact BC.

Accordingly, the work function of the shield pattern SP may be greater than or substantially equal to the work function of the storage contact BC, and lower than or substantially equal to the work function of the second dopant region SDR2 of each of the plurality of active patterns AP1 and AP2. However, the present disclosure is not limited thereto, the work function of the shield pattern SP, the work function of the second dopant region SDR2 of each of the plurality of active patterns AP1 and AP2, and the work function relationship of the storage contact BC may be variously changed.

Although not shown, in some example embodiments, when the storage contact BC is omitted and the second dopant region SDR2 of each of a plurality of active patterns AP1, and AP2 is directly connected to the cell capacitor DSP, the work function of the shield pattern SP may be lower than or substantially equal to the work function of the second dopant region SDR2. In other words, when the storage contact BC is omitted, the work function of the shield pattern SP may be the same as (or substantially similar to) or less than the work function of the second dopant region SDR2.

Here, the work function of the shield pattern SP may refer to an effective work function, and the effective work function which may be determined by the type of material contained in the shield pattern SP or the concentration of impurity. In other words, the effective work function of a specific material may refer to an intrinsic property of the material, defined as the energy required to emit an electron from an atom of the material into a vacuum when the electron is initially positioned at the fermi level within the material, and thereby the work function of a material depends on the composition of the material.

As such, when the work function of the shield pattern SP is substantially the same as or less than that of the second dopant region SDR2 of each active pattern AP1 and AP2, an electric field may be prevented from occurring between the shield pattern SP and the adjacent second dopant region SDR2. Alternatively, the electric field may be formed between them to improve the electrical characteristics of the memory transistor.

Specifically, when the work function of the shield pattern SP is the same as (or substantially similar to) that of the second dopant region SDR2, an electric field between the shield pattern SP and the second dopant region SDR2 may be prevented, thereby preventing the occurrence of gate-induced drain leakage (GIDL) current in the memory transistor. Further, when the work function of the shield pattern SP is less than that of the second dopant region SDR2, an electric field formed between the shield pattern SP and the second dopant region SDR2 may suppress the occurrence of GIDL current in the memory transistor.

In addition, when the work function of the shield pattern SP is the same as (or substantially similar to) that of the storage contact BC, an electric field between the shield pattern SP and the storage contact BC may be prevented.

Further, since the work function of the shield pattern SP is greater than that of the storage contact BC, an electric field may be formed between the shield pattern SP and the storage contact BC. In these cases, as described above, since the work function of the shield pattern SP is less than or substantially equal to the work function of the second dopant region SDR2, the gate-induced drain leakage (GIDL) current of the memory transistor may be prevented or suppressed by the storage contact BC.

In at least one example embodiment, each of the shield pattern SP and the storage contact BC may include polysilicon doped with an impurity.

Specifically, when the storage contact BC includes polysilicon doped with an impurity, the concentration of the impurity doped into the shield pattern SP may be the same as (or substantially similar to) or less than the concentration of the impurity doped into the storage contact BC. In other words, the concentration of the impurity included in the shield pattern SP may be less than or substantially equal to the concentration of the impurity included in the storage contact BC.

Further, the concentration of the impurity doped into the shield pattern SP may be the same as (or substantially similar to) or greater than the concentration of the impurity doped into the second dopant region SDR2 of each of the plurality of active patterns AP1 and AP2. In other words, the concentration of impurity included in the shield pattern SP may be greater than or substantially equal to the concentration of impurity included in the second dopant region SDR2.

This may be result of the fact that, in the subsequent heat treatment process step, as impurity diffuses from the storage contact BC to the second dopant region SDR2 of each of a plurality of active patterns AP1 and AP2, the concentration of impurity has a concentration gradient that decreases from the storage contact BC to the second dopant region SDR2. However, the present disclosure is not limited thereto, the concentration of impurity included in the shield pattern SP, the concentration of impurity included in the second dopant region SDR2 of each of the plurality of active patterns AP1 and AP2, and the concentration relationship of impurity included in the storage contact BC may be variously changed.

The effective work function of a specific material may be determined by the concentration of impurity doped into the specific material. In other words, as the concentration of the impurity doped into a specific material varies, the work function may correspondingly change due to variations in the electron density or the structure of the electrons within the specific material.

Specifically, as described above, as the concentration of impurity included in the shield pattern SP is the same as (or substantially similar to) or less than the concentration of impurity included in the storage contact BC, the effective work function of the shield pattern SP may be the same as (or substantially similar to) or greater than the effective work function of the storage contact BC.

Further, as described above, as the concentration of impurity included in the shield pattern SP is the same as (or substantially similar to) or greater than the concentration of impurity included in the second dopant region SDR2 of each of the active patterns AP1 and AP2, the effective work function of the shield pattern SP may be the same as (or substantially similar to) or less than the effective work function of the second dopant region SDR2.

In some example embodiments, when the storage contact BC and the second dopant region SDR2 of each of the plurality of active patterns AP1 and AP2 have the same (or substantially similar) concentration of impurity, the concentration of impurity included in the shield pattern SP may be the same as (or substantially similar to) the concentration of impurity included in each of the storage contact BC and the second dopant region SDR2, or greater than the concentration of impurity included in each of the storage contact BC and the second dopant region SDR2.

In these cases, the work function of the shield pattern SP may be less than each of the work function of the storage contact BC and the work function of the second dopant region SDR2, or may be the same as (or substantially similar to) each of the work function of the storage contact BC and the work function of the second dopant region SDR2. Further, the work function of the storage contact BC may be the same as (or substantially similar to) the work function of the second dopant region SDR2.

Here, the term “doped” may refer a deliberate doping process that has been performed. Further, the concentration of the impurity included in each of the shield pattern SP, the storage contact BC, and the second dopant region SDR2 of the active patterns AP1 and AP2 may refer to the average concentration of impurity included in the total area of each of the shield pattern SP, the storage contact BC, and the second dopant region SDR2.

In at least one example embodiment, the impurity included in each of the shield pattern SP, the storage contact BC, and the second dopant region SDR2 of the active patterns AP1 and AP2 may be an n-type impurity. In other words, the concentration of n-type impurity included in the shield pattern SP may be greater than or substantially equal to the concentration of n-type impurity included in the second dopant region SDR2, and the concentration of n-type impurity included in the shield pattern SP may be less than or impurity equal to the concentration of n-type impurity included in the storage contact BC.

The n-type impurity may include, for example, at least one of phosphorus (P), arsenic (As), bismuth (Bi), antimony (Sb), and/or the like. However, the present disclosure is not limited thereto, the type and/or concentration relationship of impurity included in each of the shield pattern SP, storage contact BC, and second dopant region SDR2 of the active patterns AP1 and AP2 may be variously changed.

In some example embodiments, the shield pattern SP may include a metal-containing material having a work function that is the same as (or substantially similar to) or similar to the work function of the second dopant region SDR2 of each of the active patterns AP1 and AP2.

Specifically, when the first and second active patterns AP1 and AP2 and the storage contact BC are doped with the n-type impurity, the shield pattern SP may include the metal-containing material having an n-type work function.

Here, the metal-containing material having an n-type work function may refer to a material having the work function that is the same as (or substantially similar to) or similar to the work function of polysilicon doped with the n-type impurity. For example, the work function of a metal-containing material having an n-type work function may be less than or substantially equal to the work function of the second dopant region SDR2 of active patterns AP1 and AP2, which includes the n-type impurity, and greater than or substantially equal to the work function of the storage contact BC. However, the present disclosure is not limited thereto, and the work function of a metal-containing material having an n-type work function may be variously changed.

The metal-containing material having an n-type work function may include, for example, at least one of lanthanum (La), tantalum (Ta), tantalum nitride (TaN), niobium (Nb), titanium nitride (TiN), and/or a combination thereof.

In some example embodiments, when the shield pattern SP has a multilayer structure, the shield pattern SP may contain at least one of TiN/TION, Mg/TIN, TiN/Mg/TiN, La/TiN, TiN/La/TiN, Sr/TiN, TiN/Sr/TiN, and/or combination thereof. However, the present disclosure is not limited thereto, the metal-containing material having an n-type work function included in the shield pattern SP may be variously changed.

In some example embodiments, some of the plurality of shield patterns SP may contain polysilicon doped with impurity, while others may contain the metal-containing material having an n-type work function. For example, the first shield pattern SP1 may contain polysilicon doped with impurity, and the second shield pattern SP2 may contain the metal-containing material having an n-type work function. As another example, the first shield pattern SP1 may contain the metal-containing material having an n-type work function, and the second shield pattern SP2 may contain polysilicon doped with impurity.

As the shield pattern SP is positioned between the second dopant region SDR2 of the adjacent active patterns AP1 and AP2, interference between the second dopant region SDR2 of the adjacent active patterns AP1 and AP2 may be reduced.

Further, the shield pattern SP may reduce interference between the storage contact BC connected to the second dopant region SDR2 of one of the active patterns AP1 and AP2 and the second dopant region SDR2 of the other one of the active patterns AP1 and AP2. In other words, the shield pattern SP may reduce interference between the adjacent storage contact BC and the second dopant region SDR2 of the active patterns AP1 and AP2 in the diagonal direction intersecting the second direction Y and the third direction Z in the cross-section.

In at least one example embodiment, when the shield pattern SP contains polysilicon dope with impurity, the intensity of an electric field formed between the shield pattern SP and the storage contact BC is relatively weakened compared to when the shield pattern SP contain a metallic material, so that the interference between the adjacent storage contact BC and the second dopant SDR2 of each of the active patterns AP1 and AP2 may be improved.

Further, in at least one example embodiment, when the shield pattern SP contains polysilicon doped with impurity, the work function of the shield pattern SP may be controlled by varying the concentration of impurity included in the shield pattern SP compared to when the shield pattern SP contains a metallic material.

When the shield pattern SP is formed of polysilicon doped with impurity, the concentration of the impurity included in the shield pattern SP may be adjusted based on the concentration of impurity in the active patterns AP1 and AP2, as compared to when the shield pattern SP is formed of a metallic material with a fixed work function.

Accordingly, the electric characteristics of the semiconductor device may be improved by protecting against (e.g., preventing or suppressing) the gate-induced drain leakage current of the memory transistor.

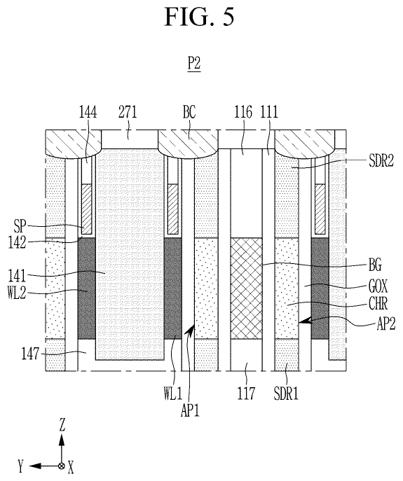

Hereinafter, semiconductor devices according to various embodiments will be described with reference to FIGS. 5 to 15. In the following example embodiments, components identical to (or substantially similar to) those in the above-described embodiment will be denoted by the same reference symbols, and a redundant description thereof will not be made or will be made in brief, and the differences in them from the above-described embodiment will be mainly described.

FIG. 5 to FIG. 11 are partial enlarged views illustrating cross-sections of semiconductor devices according to some example embodiments. Specifically, FIGS. 5 to 11 are partial enlarged views illustrating regions P2 to P8 according to some example embodiments which correspond to region P1 of FIG. 3.

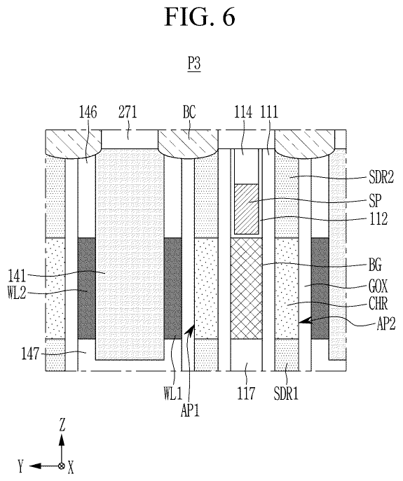

A semiconductor device according to at least one example embodiment shown in FIGS. 5 and 6 is different from the semiconductor device according to the above-described embodiment in the arrangement of the shield pattern SP.

According to the at least one example embodiment shown in FIG. 5, unlike in the semiconductor device including the region P1 according to above the at least one example embodiment, the shield pattern SP may be positioned on word lines WL1 and WL2, and may not be positioned on the back gate electrode BG. In other words, unlike in the at least one example embodiment shown in FIG. 4, the first shield pattern (see the reference symbol “SP1” in FIG. 4) which is positioned on the back gate electrode BG may be omitted.

Further, as the shield pattern SP is omitted on the back gate electrode BG, unlike the at least one example embodiment shown in FIG. 4, the first shield insulating pattern (see the reference symbol ‘113’ of FIG. 4) positioned on the back gate electrode BG may be omitted.

In the present at least one example embodiment, the shield pattern SP may be positioned on one side of the second dopant region SDR2 of each of the active patterns AP1 and AP2, and the back gate capping pattern 116 may be positioned on the other side.

Specifically, the back gate capping pattern 116 positioned on the back gate electrode BG may include a first surface and a second surface which face each other in the third direction Z. Here, the first surface may refer to the lower surface of the back gate capping pattern 116, and the second surface may refer to the upper surface.

The first surface of the back gate capping pattern 116 may be in contact with the back gate electrode BG, and the second surface may be in contact with the contact interlayer insulating layer 271. The thickness of the back gate capping pattern 116 in the third direction Z may be larger than the thickness of the shield pattern SP in the third direction Z. However, the present disclosure is not limited thereto, and the relationship between thickness of the back gate capping pattern 116 in the third direction Z and the thickness of the shield pattern SP in the third direction Z may be variously changed.

The shield pattern SP positioned on the word lines WL1 and WL2 may include first surface and second surface which face each other in the third direction Z. Here, the first surface may refer to the lower surface of the shield pattern SP, and the second surface may refer to the upper surface of the shield pattern SP.

The first surface of the back gate capping pattern 116 may be positioned at a different level from the first surface of the shield pattern SP, and the second surface of the back gate capping pattern 116 may be positioned at a different level from the second surface of the shield pattern SP. For example, the first surface of the back gate capping pattern 116 may be positioned at a lower level than the first surface of the shield pattern SP, and the second surface of the back gate capping pattern 116 may be positioned at a higher level than the second surface of the shield pattern SP.

Further, the first surface of the back gate capping pattern 116 may be positioned at the same (or a substantially similar) level as the lower surface of the shield insulating pattern 142, which surrounds the first surface of the shield pattern SP, both side surfaces of the shield pattern SP, and both side surfaces of the shield capping pattern 144. However, the present disclosure is not limited thereto, and the arrangement relationship between the back gate capping pattern 116 and the shield pattern SP and/or the arrangement relationship between the back gate capping pattern 116 and the shield insulating pattern 142 may be variously changed.

According to the at least one example embodiment shown in FIG. 6, unlike in the semiconductor device including the region P1, according to above the at least one example embodiment, the shield pattern SP may be positioned on the back gate electrode BG and may not be positioned on the word lines WL1 and WL2. In other words, unlike the at least one example embodiment shown in FIG. 4, the second shield pattern (see the reference symbol ‘SP2’ in FIG. 4) positioned on the word lines WL1 and WL2 may be omitted.

Further, as the shield pattern SP is omitted on the word lines WL1 and WL2, unlike the at least one example embodiment shown in FIG. 4, the second shield insulating pattern (see the reference symbol ‘143’ in FIG. 4) positioned on the word lines WL1 and WL2 may be omitted.

In the present at least one example embodiment, a shield pattern SP may be positioned on one side of the second dopant region SDR2 of each of the active patterns AP1 and AP2, and the word line capping layer 146 may be positioned on the other side.

Specifically, the word line capping layer 146 may include a first surface and a second surface which face each other in the third direction Z. The first surface of the word line capping layer 146 may be in contact with the word lines WL1 and WL2, and the second surface may be in contact with the storage contact BC. Here, the first surface may refer to the lower surface of the word line capping layer 146, and the second surface may refer to the upper surface.

The shield pattern SP positioned on the back gate electrode BG may include a first surface and a second surface facing each other in the third direction Z. Here, the first surface may refer to the lower surface of the shield pattern SP, and the second surface may refer to the upper surface.

The first surface of the word line capping layer 146 may be positioned at a different level from the first surface of the shield pattern SP, and the second surface of the word line capping layer 146 may be positioned at a different level from the second surface of the shield pattern SP. For example, the first surface of the word line capping layer 146 may be positioned at a lower level than the first surface of the shield pattern SP, and the second surface of the word line capping layer 146 may be positioned at a higher level than the second surface of the shield pattern SP.

In the present at least one example embodiment, the second surface of the word line capping layer 146 may include a curved surface as the second surface is recessed by the storage contact BC.

In the present at least one example embodiment, a first surface of the word line capping layer 146 may be positioned at the same (or substantially similar) level as a lower surface of the shield insulating pattern 112, which surrounds the first surface of the shield pattern SP, both side surfaces of the shield pattern SP, and both side surfaces of the shield capping pattern 114. However, the present disclosure is not limited thereto, and the arrangement relationship between the word line capping layer 146 and the shield pattern SP and/or the arrangement relationship between the word line capping layer 146 and the shield insulating pattern 112 may be variously changed.

The at least one example embodiments shown in FIG. 5 and FIG. 6 may be the result of forming the shield pattern SP positioned on the word lines WL1 and WL2 and the shield pattern SP positioned on the back gate electrode BG by separate processes. In other words, as either the process step of forming the shield pattern SP positioned on the word lines WL1 and WL2 or the process step of forming the shield pattern SP positioned on the back gate electrode BG is omitted, like in the at least one example embodiments shown in FIGS. 5 and 6, on only either the word lines WL1 and WL2 or the back gate electrode BG, the shield pattern SP may be formed.

According to the semiconductor device according to the at least one example embodiments shown in FIG. 5 and FIG. 6, may have the same (or a substantially similar) effect as the semiconductor device according to the above embodiment. In other words, as the shield pattern SP is formed on one side of each of the active patterns AP1 and AP2, coupling due to interference between the dopant regions of the active patterns AP1 and AP2 adjacent to each other with the word lines WL1 and WL2 interposed therebetween or between the dopant regions of the active patterns AP1 and AP2 adjacent to each other with the back gate electrode BG interposed therebetween may be improved.

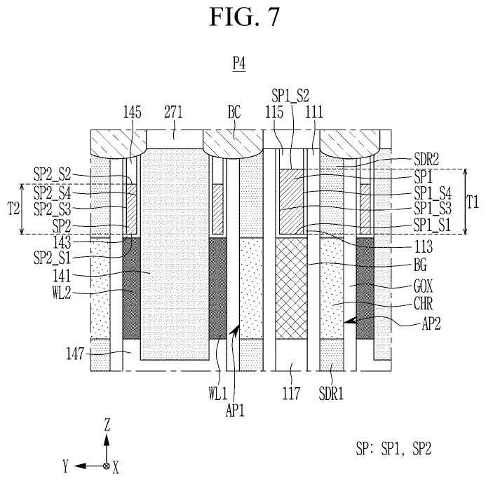

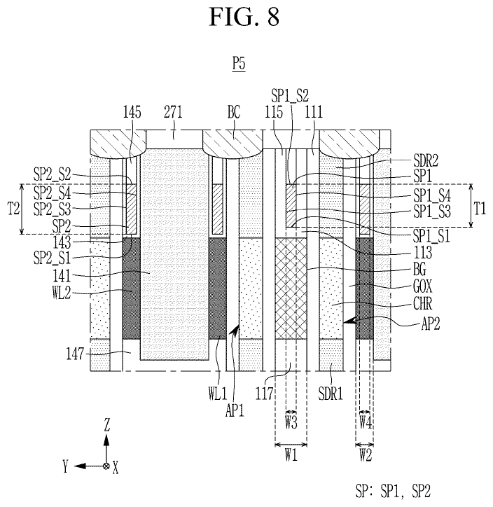

According to the semiconductor device according to the example embodiments shown in FIG. 7 and FIG. 8, the thickness and/or width of the shield pattern SP is different compared to the semiconductor devices according to the above example embodiments.

According to the semiconductor device according to the at least one example embodiment shown in FIG. 7, is difference from the semiconductor device including the region P1 according to the above embodiment in that the thickness of the first shield pattern SP1 in the third direction Z is different from the thickness of the second shield pattern SP2 in the third direction Z.

In the present at least one example embodiment, the thickness of the first shield insulating pattern 113 surrounding the first shield pattern SP1 and the thickness of the second shield insulating pattern 143 surrounding the second shield pattern SP2 may be the same or substantially similar.

In the present at least one example embodiment, the first shield pattern SP1 may have a first thickness T1, and the second shield pattern SP2 may have a second thickness T2. The first thickness T1 may be larger than the second thickness T2. In other words, the thickness of the first shield pattern SP1 may be larger than the thickness of the second shield pattern SP2. However, the present disclosure is not limited thereto, and the relationship between first thickness T1 and second thickness T2 may be variously changed. For example, first thickness T1 may be smaller than second thickness T2.

In the present at least one example embodiment, the first surface SP1_S1 of the first shield pattern SP1 may be positioned at the same or a substantially similar level as the first surface SP2_S1 of the second shield pattern SP2, and the second surface SP1_S2 of the first shield pattern SP1 may be positioned at a higher level than the second surface SP2_S2 of the second shield pattern SP2. However, the present disclosure is not limited thereto, and as the thickness relationship between the first shield pattern SP1 and the second shield pattern SP2 and/or the thickness relationship between the first shield insulating pattern 113 and the second shield insulating pattern 143 are variously changed, the arrangement relationship between the first shield pattern SP1 and the second shield pattern SP2 may be variously changed. For example, as the second thickness T2 of the second shield pattern SP2 is larger than the first thickness T1 of the first shield pattern SP1, the first surface SP1_S1 of the first shield pattern SP1 may be positioned at the same (or a substantially similar) level as the first surface SP2_S1 of the second shield pattern SP2, and the second surface SP1_S2 of the first shield pattern SP1 may be positioned at a lower level than the second surface SP2_S2 of the second shield pattern SP2.

According to the semiconductor device according to the at least one example embodiment shown in FIG. 8, is a difference from the semiconductor device including the region P1, according to the above embodiment shown in FIG. 4 in that the thicknesses of the first shield insulating pattern 113 and the second shield insulating pattern 143 are different.

In the present at least one example embodiment, the thickness of the first shield insulating pattern 113 which is surrounds the first surface SP1_S1 and both side surfaces SP1_S3 and SP1_S4 of the first shield pattern SP1 may be different from the thickness of the second shield insulating pattern 143 which surrounds the first surface SP2_S1 and both side surfaces SP2_S3 and SP2_S4 of the second shield pattern SP2. For example, the thickness of the first shield insulating pattern 113 in the second direction Y and the thickness in the third direction Z may be larger than the thickness of the second shield insulating pattern 143 in the second direction Y and the thickness in the third direction Z, respectively.

Accordingly, the first shield pattern SP1 according to the present at least one example embodiment may have a smaller width in the second direction Y compared to the first shield pattern SP1 according to the at least one example embodiment shown in FIG. 4.

In the present at least one example embodiment, the third width W3 may be smaller than the first width W1 and the second width W2, and smaller than or the same as (or substantially similar to) the fourth width W4. In other words, the width of the first shield pattern SP1 may be smaller than the widths of the back gate electrode BG and the word lines WL1 and WL2, respectively, and smaller than or the same as (or substantially similar to) the width of the second shield pattern SP2. However, the present disclosure is not limited thereto, the relationship between the first width W1, the second width W2, the third width W3, and the fourth width may be variously changed. For example, unlike as shown in FIG. 8, the third width W3 may be smaller than the first width W1 and the second width W2, and larger than or the same as (or substantially similar to) the fourth width W4. In other words, the width of the first shield pattern SP1 may be smaller than the widths of the back gate electrode BG and word lines WL1 and WL2, respectively, and larger than or the same as (or substantially similar to) the width of the second shield pattern SP2.

In the present at least one example embodiment, the first thickness T1 of the first shield pattern SP1 may be smaller than the second thickness T2 of the second shield pattern SP2. However, the present disclosure is not limited thereto, and the relationship between first thickness T1 and second thickness T2 may be variously changed.

As described above, as the thickness of the first shield insulating pattern 113 in the third direction Z is larger than the thickness of the second shield insulating pattern 143 in the third direction Z, the first surface SP1_S1 of the first shield pattern SP1 may be positioned at a higher level than the first surface SP2_S1 of the second shield pattern SP2, and the second surface SP1_S2 of the first shield pattern SP1 may be positioned at substantially the same level as the second surface SP2_S2 of the second shield pattern SP2. However, the present disclosure is not limited thereto, and the arrangement relationship between the first shield pattern SP1 and the second shield pattern may be variously changed.

Unlike as shown in FIG. 8, in some example embodiments, when the first thickness T1 is smaller than the second thickness T2, due to the thickness difference between the first shield insulating pattern 113 and the second shield insulating pattern 143, the first surface SP1_S1 of the shield pattern SP1 may be positioned at a higher level than the first surface SP2_S1 of the second shield pattern SP2, and the second surface SP1_S2 of the first shield pattern SP1 may be positioned at a higher level than the second surface SP2_S2 of the second shield pattern SP2.

Unlike FIG. 8, in some example embodiments, when the first thickness T1 is larger than or the same as (or substantially similar to) the second thickness T2, the first surface SP1_S1 of the shield pattern SP1 may be positioned at a higher level than the first surface SP2_S1 of the second shield pattern SP2, and the second surface SP1_S2 of the first shield pattern SP1 may be positioned at a higher level than the second surface SP2_S2 of the second shield pattern SP2, due to the thickness difference between the first shield insulating pattern 113 and the second shield insulating pattern 143.

In FIG. 8, the relationship of the widths and arrangement of the first shield pattern SP1 and the second shield pattern SP2 are described when the thickness of the first shield insulating pattern 113 is larger than the thickness of the second shield insulating pattern 143. However, unlike as shown in FIG. 8, in some example embodiments, the thickness of the first shield insulating pattern 113 may be smaller than the thickness of the second shield insulating pattern 143.

In this case, the above-described content regarding the arrangement relationship between the first shield pattern SP1 and the second shield pattern SP2 due to the difference thickness between the first shield insulating pattern 113 and the second shield insulating pattern 143 may be applied substantially the same, and thus a detailed description thereof will not be made.

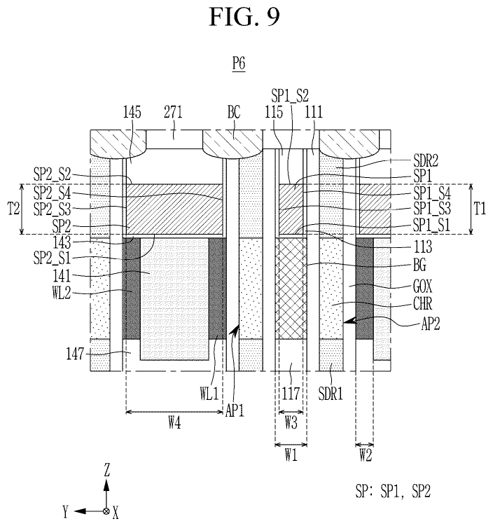

According to the semiconductor device according to the at least one example embodiment shown in FIG. 9, is a difference from the semiconductor device according to the above embodiment in that the width and arrangement of the second shield pattern SP2 positioned on the word lines WL1 and WL2 are different.

The description of the first shield pattern SP1 described above with reference to FIG. 4 may be the same as or substantially similarly applied to the first shield pattern SP1 according to the present at least one example embodiment, and thus, a detailed description thereof will not be made.

Referring to FIG. 9, the back gate electrode BG may have a first width W1, the word lines WL1 and WL2 may have a second width W2, respectively, the first shield pattern SP1 may have a third width W3, and the second shield pattern SP2 may have a fourth width W4.

Here, the first width W1, the second width W2, the third width W3, and the fourth width W4 may refer to the width in the second direction Y.

In the present at least one example embodiment, the first width W1 may be larger than the second width W2 and the third width W3, and smaller than the fourth width W4. In other words, the width of the back gate electrode BG may be larger than the width of the first shield pattern SP1 and the word lines WL1 and WL2, respectively, and smaller than the width of the second shield pattern SP2.

The second width W2 may be smaller than the first width W1, the third width W3, and the fourth width W4. That is, the widths of word lines WL1 and WL2 may be smaller than the widths of the back gate electrode BG, the first shield pattern SP1, and the second shield pattern SP2, respectively.

The third width W3 may be smaller than the first width W1 and the fourth width W4, and larger than the second width W2. In other words, the width of the first shield pattern SP1 may be smaller than the widths of the back gate electrode BG and the second shield pattern SP, and larger than the widths of each of the word lines WL1 and WL2.

The fourth width W4 may be larger than the first width W1, the second width W2, and the third width W3. In other words, the width of the second shield pattern SP2 may be larger than the widths of the back gate electrode BG, the first shield pattern SP1, and word lines WL1, and WL2, respectively.

Accordingly, the width of the first shield capping pattern 115 positioned on the first shield pattern SP1 may be smaller than the width of the second shield capping pattern 145 positioned on the second shield pattern SP2.

In the present at least one example embodiment, the second shield pattern SP2 may be positioned on the word lines WL1, and WL2, which are positioned between the first active pattern AP1 and the second active pattern AP2. In other words, the second shield pattern SP2 may be positioned to overlap the first word line WL1 and the second word line WL2 in the third direction Z.

Accordingly, the second shield pattern SP2 may be positioned to overlap the plurality of word lines WL1 and WL2 in the third direction Z.

Further, the second shield pattern SP2 may be positioned to overlap with the gate isolation pattern 141 in the third direction Z. The second shield pattern SP2 may cover the first word line WL1, the second word line WL2, and the gate isolation pattern 141.

In the present at least one example embodiment, the thickness of the first shield insulating pattern 113, which surrounds the first surface SP1_S1 and both side surfaces SP1_S3 and SP1_S4 of the first shield pattern SP1, may be the same as (or substantially similar to) the thickness of the second shield insulating pattern 143, which surrounds the first surface SP2_S1 and both side surfaces SP2_S3 and SP2_S4 of the second shield pattern SP2. However, the present disclosure is not limited thereto, and the thickness of the first shield insulating pattern 113 and the thickness of the second shield insulating pattern 143 may be different.

In the present at least one example embodiment, the second shield insulating pattern 143 may be positioned between the second shield pattern SP2 and the word lines WL1, and WL2, and between the second shield pattern SP2 and the gate isolation pattern 141. The second shield insulating pattern 143 may extend along the first surface SP2_S1 of the second shield pattern SP2 and may cover the word lines WL1 and WL2, and the gate isolation pattern 141.

In the present at least one example embodiment, the first shield pattern SP1 has a first thickness T1, the second shield pattern SP2 has a second thickness T2, and the first thickness T1 may be the same as (or substantially similar to) the second thickness T2.

Accordingly, the first surface SP1_S1 of the first shield pattern SP1 may be positioned at substantially the same level as the first surface SP2_S1 of the second shield pattern SP2, and the second surface SP1_S2 of the first shield pattern SP1 may be positioned at substantially the same level as the second surface SP2_S2 of the second shield pattern SP2. However, the present disclosure is not limited thereto, and as the thickness of the first shield insulating pattern 113 and the thickness of the second shield insulating pattern 143 are different, the arrangement relationship between the first shield pattern SP1 and the second shield pattern SP2 may be variously changed.

Unlike as shown in FIG. 9, in some example embodiments, the first thickness T1 of the first shield pattern SP1 may be different from the second thickness T2 of the second shield pattern SP2. For example, the first thickness T1 may be larger than second thickness T2. As another example, the first thickness T1 may be smaller than the second thickness T2.

Accordingly, the arrangement relationship between the first shield pattern SP1 and the second shield pattern SP2 may be variously changed.

The semiconductor devices according to the at least one example embodiments shown in FIG. 9 may have substantially the same effect as that of the semiconductor device according to the above embodiment.

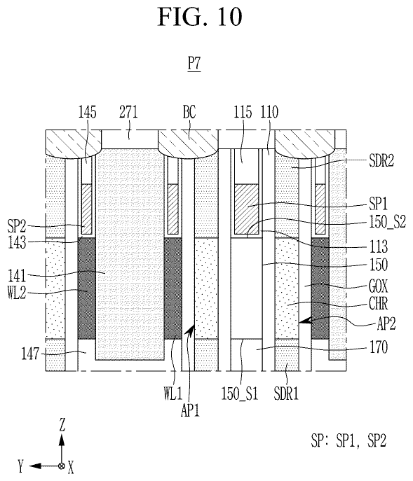

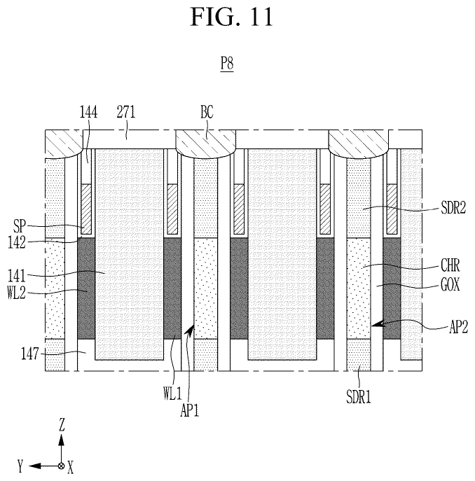

The semiconductor devices according to the at least one example embodiments shown in FIGS. 10 and 11 are difference from the semiconductor device according to the above embodiment in that the back gate electrode BG is omitted.

According to the semiconductor device according to the at least one example embodiment shown in FIG. 10, unlike the at least one example embodiment shown in FIG. 4, the back gate electrode (see the reference symbol ‘BG’ in FIG. 4) and the back gate insulating pattern (see the reference symbol ‘111’ in FIG. 4) are omitted, and an isolation insulating pattern 150 and an isolation capping pattern 170 positioned between the first active pattern AP1 and the second active pattern AP2 may be further included.

Further, according to the present at least one example embodiment, a liner insulating pattern 110 may further be included to surround the side surfaces of the isolation insulation pattern 150, the isolation capping pattern 170, and the first shield insulating pattern 113.

Specifically, referring to FIG. 10, the first word line WL1 may be positioned on one side in the second direction Y of one of the active patterns AP1 and AP2, and the isolation insulating pattern 150 may be positioned on the other side in the second direction Y. Further, the isolation insulating pattern 150 may be positioned on one side in the second direction Y of the other one of the active patterns AP1 and AP2, and the second word line WL2 may be positioned on the other side in the second direction Y.

Accordingly, the word lines WL1 and WL2 may be positioned only on either one of the one side or the other side of the active patterns AP1 and AP2.

The isolation insulating pattern 150 may include a first surface 150_S1 and a second surface 150_S2 which face each other in the third direction Z. Here, the first surface 150_S1 may refer to the lower surface of the isolation insulating pattern 150, and the second surface 150_S2 may refer to the upper surface.

The first surface 150_S1 of the isolation insulating pattern 150 may be positioned at substantially the same level as the first surface of each of the word lines WL1 and WL2, and the second surface 150_S2 may be positioned at substantially the same level as the second surface of each of the word lines WL1 and WL2. However, the present disclosure is not limited thereto, and the arrangement relationship of the isolation insulating pattern 150 and the word lines WL1 and WL2 may be variously changed.

In the present at least one example embodiment, the first shield pattern SP1 may be positioned on the isolation insulating pattern 150, and the second shield pattern SP2 may be positioned on the word lines WL1 and WL2, respectively.

The description of the first shield pattern SP1 and the second shield pattern SP2 described above with reference to FIGS. 4 to 9 may be substantially similarly applied to the first shield pattern SP1 and the second shield pattern SP2 according to the present at least one example embodiment, and thus, a detailed description thereof will not be made.

The isolation capping pattern 170 may be positioned on the first surface 150_S1 of the isolation insulating pattern 150.

The liner insulating pattern 110 may extend in the third direction Z along each side surface of the sequentially stacked the isolation capping pattern 170, the isolation insulating pattern 150, and the first shield insulating pattern 113.

The first shield insulating pattern 113 may be positioned between the isolation insulating pattern 150 and the first shield pattern SP1. The first shield insulating pattern 113 may be positioned between the first shield pattern SP1 and the liner insulating pattern 110, and between the first shield capping pattern 115 and the liner insulating pattern 110.

Each of the liner insulating pattern 110, the isolation insulating pattern 150, and the isolation capping pattern 170 may contain an insulating material. For example, the insulating material may contain silicon oxide, silicon nitride, silicon oxynitride, and the like, but is not limited thereto, and may be variously changed.

According to the semiconductor device according to the at least one example embodiment shown in FIG. 11, unlike the at least one example embodiment shown in FIG. 4, the back gate electrode (see the reference symbol ‘BG’ in FIG. 4), the back gate insulating pattern (see the reference symbol ‘111’ in FIG. 4), the first shield insulating pattern (see the reference symbol ‘113’ in FIG. 4), the first shield pattern (see the reference symbol ‘SP1’ in FIG. 4), and the first shield capping pattern (see the reference symbol ‘115’ in FIG. 4) positioned between the first active pattern AP1 and the second active pattern AP2 are omitted, and the first word line WL1 and the second word line WL2 are further included between the first active pattern AP1 and the second active pattern AP2.

Referring to FIG. 11, the first word line WL1 and the second word line WL2 may be positioned between the active patterns AP1 and AP2, respectively.

Specifically, the first word line WL1 may be positioned on one side of the first active pattern AP1 in the second direction Y, and the second word line WL2 may be positioned on the other side in the second direction Y.

Further, the first word line WL1 may be positioned on one side of the second active pattern AP2 in the second direction Y, and the second word line WL2 may be positioned on the other side in the second direction Y.

Accordingly, the word lines WL1 and WL2 may be positioned on both sides of each of the first active pattern AP1 and the second active pattern AP2.

In the present at least one example embodiment, the plurality of shield patterns SP may be positioned on the plurality of word lines WL1, and WL2, respectively.

The plurality of shield patterns SP each may have substantially the same thickness in the third direction Z and/or width in the second direction Y. However, the present disclosure is not limited thereto, and the above description of the shield pattern SP made with reference to FIGS. 5 to 9 may be equally applied to the arrangement relationship, width relationship, thickness relationship, and so on of the plurality of shield patterns SP, and thus a detailed description thereof will not be made.

In FIG. 11, it is shown that two side surfaces of the side surfaces of each of the first active pattern AP1 and the second active pattern AP2 overlap the word lines WL1 and WL2. However, the arrangement relationship of the first and second active patterns AP1 and AP2 and the word lines WL1 and WL2 is not limited thereto, and may be variously changed.

Unlike as shown in FIG. 11, in some example embodiments, the word lines WL1 and WL2 may surround both side surfaces of the first active pattern AP1 and the second active pattern AP2, respectively. For example, the word lines WL1 and WL2 may be integrally formed, and have a gate-all-around (GAA) structure which surrounds four side surfaces of each of the first active pattern AP1 and the second active pattern AP2.

When the word lines WL1 and WL2 are integrally formed and have a structure which surrounds all of the side surfaces of each of the first active pattern AP1 and the second active pattern AP2 as described above, the shield pattern SP, which are positioned on the first word line WL1 and the second word line WL2, the shield insulating pattern 142, and the shield capping pattern 144, respectively, may be integrally formed and have a structure which surrounds all of the side surfaces of each of the first active pattern AP1 and the second active pattern AP2.

According to the semiconductor device according to the at least one example embodiments shown in FIG. 10 and FIG. 11, may have the same or a substantially similar effect as the semiconductor device according to the above embodiment.

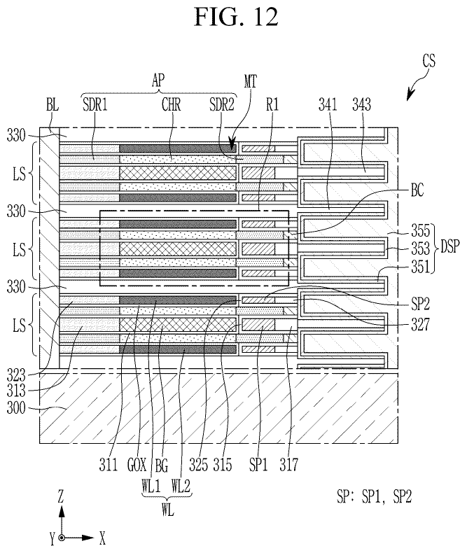

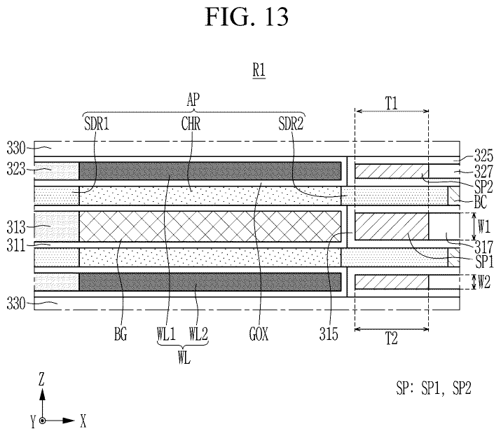

FIG. 12 is a cross-sectional view illustrating a cross-section of a semiconductor device according to some example embodiments. FIG. 13 is an enlarged view of region R1 of FIG. 12.

Specifically, FIG. 12 is a cross-sectional view illustrating a substrate 300 of the semiconductor device according to some example embodiments and a cell structure CS which is positioned on the substrate 300. The semiconductor device according to the at least one example embodiment shown in FIG. 12 may be a vertically stacked DRAM (VS DRAM).

The semiconductor device according to the at least one example embodiment may include a plurality of memory cells arranged three-dimensionally. The plurality of memory cells may include one memory transistor MT and one cell capacitor DSP. Each of the plurality of memory cells may be connected to a bit line BL and a word line WL. In the present at least one example embodiment, two word lines WL may share one back gate electrode BG.

The semiconductor device according to the at least one example embodiment may include the substrate 300, and the cell structure CS which is positioned on the substrate 300.

The cell structure CS may include the substrate 300, a bit line BL which extends in the third direction Z perpendicular to the substrate 300, a plurality of active patterns AP which are connected to the bit line BL and extends in the first direction X parallel with the substrate 300, a pair of word lines WL which are positioned on both sides of the plurality of active patterns AP, a back gate electrode BG which is positioned between active patterns AP adjacent to each other, a cell capacitor DSP which is connected to the plurality of active patterns AP, and a plurality of shield patterns SP which is positioned at a level between a word line WL and the cell capacitor DSP and/or at a level between the back gate electrode BG and the cell capacitor DSP.

In FIG. 12, it is shown that the semiconductor device according to the present at least one example embodiment includes three memory cells which are connected in common to one bit line BL and stacked in the third direction Z perpendicular to the substrate 300, however, the present disclosure is not limited thereto.

Further, in FIG. 12, it is shown that each stack structure LS includes one memory cell, however, the present disclosure is not limited thereto. For example, each stack structure LS may further include a memory cell mirror-symmetrical to the structure of the memory cell shown in FIG. 12. For example, the semiconductor device according to some example embodiments may further include a stack structure mirror-symmetrical to the stack structure LS of FIG. 12 and positioned on the substrate 300. The stack structure LS and the stack structure mirror-symmetrical to the stack structure LS may form a pair.

Specifically, the substrate 300 may be a semiconductor substrate, for example, a silicon substrate, a germanium substrate, or a silicon-germanium substrate. A plurality of stack structures LS may be sequentially stacked on the substrate 300. Each stack structure LS may constitute the memory cell array of the semiconductor device.

Although it is shown in FIG. 12, the semiconductor device according to the present at least one example embodiment may further include a peripheral circuit structure (not shown in the drawings) including a peripheral circuit for operating the memory cell array.

The peripheral circuit structure may include wiring lines which are electrically connected to the bit lines BL and the word lines WL, and the wiring lines may be connected to the peripheral circuit. The peripheral circuit structure may be positioned on or below the cell structure CS so as to overlap it in the third direction Z. For example, the cell structure CS and the peripheral circuit structure may be bonded and coupled by a hybrid copper bonding method substantially like in the semiconductor device according to the above embodiment. However, the bonding method of the cell structure CS and the peripheral circuit structure is not limited thereto. For example, the cell structure CS and the peripheral circuit structure may be connected in a direct bonding manner by the single through-hole via.

Referring to FIGS. 12 and 13, on one side of the plurality of stack structures LS, a bit line BL may be positioned. The bit line BL may extend in the third direction Z perpendicular to the substrate 300. The bit line BL may have a line shape or a column shape extending in the third direction Z.

Each of the plurality of stack structures LS may include an active pattern AP, a pair of word lines WL which are positioned on both sides of the active pattern AP in the third direction Z, and a cell capacitor DSP which is connected to the active pattern AP. The pair of word lines WL may be positioned on both sides of the active pattern AP in the third direction Z.

The active pattern AP may extend in the first direction X vertically intersecting the extension direction of the bit line BL. In other words, the active pattern AP may extend in the first direction X parallel with the substrate 300.

The active pattern AP may include a first dopant region SDR1 which is connected to the bit line BL, a second dopant region SDR2 which is connected to the cell capacitor DSP, and a channel region CHR which is positioned between the first and second dopant regions SDR1 and SDR2. The first and second dopant regions SDR1 and SDR2 of each of the active patterns AP1 and AP2 may correspond to the first source/drain electrode and second source/drain electrode of a memory transistor MT, and the channel region CHR may correspond to the channel of the memory transistor MT.

The above description of the active pattern AP made with reference to FIG. 4 may also be substantially equally applied to the active pattern AP according to the present at least one example embodiment, and thus a detailed description thereof will not be made.

The semiconductor device according to the present at least one example embodiment may further include an interlayer insulating layer 330 which is positioned between stack structures LS adjacent to each other.

The word lines WL, the active pattern AP, the back gate electrode BG, and the cell capacitor DSP which are included in each stack structure LS may be positioned on the interlayer insulating layer 330. The interlayer insulating layer 330 may be positioned between the substrate 300 and the stack structure LS positioned at the lowest level.

The interlayer insulating layer 330 may contain an insulating material, for example, at least one of silicon nitride, silicon oxynitride, carbon containing silicon oxide, carbon containing silicon nitride, carbon containing silicon oxynitride, a combination thereof, and/or the like.

The plurality of word lines WL may extend in the first direction X, which intersects perpendicularly with a third direction Z, the extending direction of a bit line BL. The plurality of word lines WL may extend in the first direction X parallel with the upper surface of the substrate 300.

The stack structure LS may include two word lines WL. The stack structure LS may include a first word line WL1 and a second word line WL2 spaced apart in the third direction Z. Between the first word line WL1 and the second word line WL2 spaced apart in the third direction Z, two active patterns AP may be positioned.

Each word line WL may be positioned so as to correspond to the channel region CHR of an active pattern AP. The first word line WL1 may be positioned on one side in the third direction Z of the channel region CHR of any one of the plurality of active patterns AP positioned adjacent to each other, and the second word line WL2 may be positioned on the other side in the third direction Z of the channel region CHR of the other one of the plurality of active patterns AP positioned adjacent to each other.

The material which is contained in the bit line BL and the word line WL according to the present at least one example embodiment is the same as (or substantially similar to) the material which is contained in the bit line BL and the word lines (see the reference symbols “WL1” and “WL2” in FIG. 4) included in the semiconductor device according to the above embodiment, and a detailed description thereof will not be made.

The semiconductor device according to the present at least one example embodiment may further include a gate capping pattern 323 which is positioned between the bit line BL and the word line WL, and a gate insulating pattern GOX which surrounds the side surface of the word line WL and the gate capping pattern 323.

The gate capping pattern 323 may contain an insulating material, and insulate the bit line BL and the word line WL from each other. For example, the gate capping pattern 323 may contain silicon oxide, silicon nitride, or a combination thereof.

The gate insulating pattern GOX may cover the side surfaces of the gate capping pattern 323 and the word line WL so as to conform to them.

The material which is contained in the gate insulating pattern GOX according to the present at least one example embodiment is the same as (or substantially similar to) the material which is contained in the gate insulating pattern GOX included in the semiconductor device according to the above embodiment, and thus, a detailed description thereof will not be made.

The stack structure LS may include one back gate electrode BG. The back gate electrode BG may be positioned between the first word line WL1 and the second word line WL2. The back gate electrode BG may be positioned between the active patterns AP adjacent to each other in the third direction Z. The back gate electrode BG may be positioned so as to correspond to the channel region CHR of an active pattern AP.

On one side of the active pattern AP in the third direction Z, the word line WL may be positioned, and on the other side in the third direction Z, the back gate electrode BG may be positioned. On both sides of the active pattern AP facing each other in the third direction Z, the word line WL and the back gate electrode BG may be positioned, respectively.

The material which is contained in the back gate electrode BG according to the present at least one example embodiment is the same as (or substantially similar to) the material which is contained in the back gate electrode BG included in the semiconductor device according to the above embodiment, and a detailed description thereof will not be made.

Further, in the present at least one example embodiment, regarding the arrangement relationship of the word line WL and the back gate electrode BG and/or the width relationship in the third direction Z between the word line WL and the back gate electrode BG the contents about the arrangement relationship of the word lines (see the reference symbols “WL1” and “WL2” in FIG. 4) and the back gate electrode BG (see the reference symbols “BG” in FIG. 4) and the width relationship between the word lines (see the reference symbols “WL1” and “WL2” in FIG. 4) and the back gate electrode (see the reference symbols “BG” in FIG. 4) according to the above embodiment may be substantially equally applied, and thus, a detailed description thereof will not be made.

The semiconductor device according to the present at least one example embodiment may further include a back gate capping pattern 313 which is positioned between the bit line BL and the back gate electrode BG, and a back gate insulating pattern 311 which surrounds the side surfaces of the back gate electrode BG and the back gate capping pattern 313.

The back gate capping pattern 313 may contain an insulating material, and insulate the bit line BL and the back gate electrode BG from each other. The back gate insulating pattern 311 may cover the side surfaces of the back gate capping pattern 313 and the back gate electrode BG so as to conform to them.

The back gate insulating pattern 311 and the back gate capping pattern 313 may contain silicon oxide, silicon nitride, or a combination thereof. However, the present disclosure is not limited thereto.

The plurality of shield patterns SP may be positioned between the word line WL and the cell capacitor DSP and between the back gate electrode BG and the cell capacitor DSP.

In the present at least one example embodiment, the shield pattern SP may overlap the second dopant region SDR2 of at least one of the plurality of active patterns AP in the third direction Z which is a vertical direction. For example, the shield pattern SP may be positioned so as to overlap the second dopant region SDR2 of each of the plurality of active pattern AP in the third direction Z which is the vertical direction. The shield pattern SP may be positioned so as to overlap a portion of the active pattern AP in the third direction Z which is the extension direction of the bit line BL. In other words, the shield pattern SP may be positioned to overlap the second dopant region SDR2 of each of the plurality of active patterns AP in the third direction Z, which intersects perpendicularly with the first direction X in which the word line WL extends.

In the present at least one example embodiment, the plurality of shield patterns SP may be positioned on at least one of a back gate electrode BG and a plurality of word lines WL. For example, as shown in FIG. 12, the plurality of shield patterns SP may be positioned on each of the back gate electrode BG and a plurality of word lines WL.

The plurality of shield patterns SP may include a first shield pattern SP1 which is positioned on the back gate electrode BG, and a second shield pattern SP2 which is positioned on the word line WL.

The first shield pattern SP1 may be positioned between the back gate electrode

BG and the cell capacitor DSP, and the second shield pattern SP2 may be positioned between the word line WL and the cell capacitor DSP.

In FIG. 12, it is shown that the plurality of shield patterns SP is positioned between the back gate electrode BG and the cell capacitor DSP and between the word line WL and the cell capacitor DSP, respectively, but the arrangement of the plurality of patterns SP is not limited thereto and may be variously changed. Although not shown in the drawing, for example, the plurality of patterns SP may be arranged substantially in the same manner as that of the patterns SP according to the at least one example embodiment shown in FIGS. 5 and 6.

Between a first shield pattern SP1 and the back gate electrode BG, the back gate insulating pattern 311 may be positioned, and between the second shield pattern SP2 and the word line WL, the gate insulating pattern GOX may be positioned.

Each first shield pattern SP1 may be positioned so as to overlap the back gate electrode BG in the first direction X, and the second shield pattern SP2 may be positioned so as to overlap the word line WL in the first direction X. In other words, the first shield pattern SP1 and the back gate electrode BG may be positioned parallel along the first direction X, and the second shield pattern SP2 and the word line WL may be positioned parallel along the first direction X.

Each first shield pattern SP1 may extend in the first direction X between the back gate electrode BG and the cell capacitor DSP, and the second shield pattern SP2 may extend in the first direction X between the word line WL and the cell capacitor DSP.

The plurality of shield patterns SP may be positioned between active patterns AP adjacent to each other in the third direction Z. The length of each shield pattern SP in the first direction X may be smaller than the lengths of the active patterns AP1 and AP2 in the first direction X.

The length of a shield pattern SP in the first direction X may be smaller than the length of the second dopant region SDR2 in the first direction X. Accordingly, the shield pattern SP may overlap a portion of the second dopant region SDR2 in the third direction Z.

Besides that, regarding the material, arrangement relationship, width relationship, thickness relationship, the concentration of impurity, and the work function of the plurality of shield patterns SP, and so on, the above contents described with reference to FIGS. 1 to 11 may be substantially equally applied, and thus, a detailed description thereof will not be made.

The semiconductor device according to the present at least one example embodiment may further include a first shield insulating pattern 315 which is positioned between the back gate electrode BG and the first shield pattern SP1, a first shield capping pattern 317 which is positioned between the first shield pattern SP1 and the cell capacitor DSP, a second shield insulating pattern 325 which is positioned between the word line WL and the second shield pattern SP2, and a second shield capping pattern 327 which is positioned between the second shield pattern SP2 and the cell capacitor DSP.

The first shield insulating pattern 315 may be positioned between the first shield pattern SP1 and the second dopant SDR2 of the active pattern AP, and between the first shield pattern SP1 and the back gate insulating pattern 311. The first shield insulating pattern 315 may extend conformally along the surfaces of the first shield pattern SP1 and the first shield capping pattern 317.

The second shield insulating pattern 325 may be positioned between the second shield pattern SP2 and the second dopant SDR2 of the active pattern AP, and between the second shield pattern SP2 and the gate insulating pattern GOX. The second shield insulating pattern 325 may extend conformally along the surfaces of the second shield pattern SP2 and the second shield capping pattern 327.

The first shield insulating pattern 315, the first shield capping pattern 317, the second shield insulating pattern 325, and the second shield capping pattern 327 may contain an insulating material. For example, the insulating material may include at least one of silicon oxide, silicon nitride, a combination thereof, and/or the like. However, the insulating material is not limited thereto, and may be variously changed.

The cell capacitor DSP may include a first electrode 351, a second electrode 355, and a dielectric layer 353 which is interposed between the first electrode 351 and the second electrode 355.

The contents about the first electrode (see the reference symbol “251” in FIG. 3), the second electrode (see the reference symbol “252” in FIG. 4), and the dielectric layer (see the reference symbol “253” in FIG. 3) included in the cell capacitor DSP according to the above embodiment may also be substantially equally applied to the first electrode 351, the second electrode 355, and the dielectric layer 353 included in the cell capacitor DSP according to the present at least one example embodiment, and thus, a detailed description thereof will not be made.

In the present at least one example embodiment, the storage contact BC may be positioned between the second dopant region SDR2 of the active pattern AP and the cell capacitor DSP. The storage contact BC may be in contact with the cell capacitor DSP. For example, the storage contact BC may be connected to the first electrode 351 of the cell capacitor DSP.

In the present at least one example embodiment, the storage contact BC overlaps the shield pattern SP in the third direction Z and may not overlap the shield capping patterns 317 and 327. However, the present disclosure is not limited thereto, and unlike as shown in FIG. 12, in some example embodiments, the storage contact BC may overlap with at least a portion of the shield pattern SP in the third direction Z.

Unlike shown in FIG. 12, in some example embodiments, the storage contact BC may be omitted. When the storage contact BC is omitted, the second dopant region SDR2 of the active pattern AP may be directly connected to the first electrode 351 of the cell capacitor DSP.

Besides that, the storage contact BC according to the present at least one example embodiment may be the same as (or substantially similar to) the storage contact BC according to the at least one example embodiment shown in FIG. 4, and thus, a detailed description thereof will not be made. In other words, the description of the type of impurity and concentration of impurity included in the storage contact BC, and work function of the storage contact BC according to the present at least one example embodiment may be the same as (or substantially similar to) that the description of the storage contact BC described above with reference to FIG. 4.

The semiconductor device according to the present at least one example embodiment may further include first and second capacitor isolation patterns 341 and 343 which are positioned between the first electrode 351 of the cell capacitor DSP.

The first and second capacitor isolation patterns 341 and 343 may be positioned between the first electrodes 351 of the cell capacitors DSP, and alternately stacked in the third direction Z.

The first capacitor isolation pattern 341 may extend in the first direction X from the interlayer insulating layer 330, and the second capacitor isolation pattern 343 may extend in the first direction X from the first shield capping pattern 317. The first electrode 351 of each cell capacitor DSP may be isolated and insulated by the first and second capacitor isolation patterns 341 and 343.

The first and second capacitor isolation patterns 341 and 343 may contain an insulating material such as silicon oxide. However, the present disclosure is not limited thereto.

As shown in FIG. 13, the first shield pattern SP1 may have a first thickness T1, and the second shield pattern SP2 may have a second thickness T2.

Here, first thickness T1 and second thickness T2 may refer to thickness in the first direction X. In other words, the first thickness T1 and the second thickness T2 may refer to the thickness of the first shield pattern SP1 and the second shield pattern SP2 in their extension directions, respectively.

In the present at least one example embodiment, the first thickness T1 may be the same as (or substantially similar to) the second thickness T2. Further, the thickness of the first shield insulating pattern 315 surrounding the first shield pattern SP1 and the thickness of the second shield insulating pattern 325 surrounding the second shield pattern SP2 may be substantially the same. However, the present disclosure is not limited thereto, and the relationship between the first thickness T1 and the second thickness T2 and/or the thickness relationship between the first shield insulating pattern 315 and the second shield insulating pattern 325 may be variously changed.

Unlike as illustrated in FIG. 13, in some example embodiments, the relationship between the first thickness T1 and the second thickness T2 and/or the thickness relationship between the first shield insulating pattern 315 and the second shield insulating pattern 325, the content about the relationship between the first thickness T1 and the second thickness T2 according to the at least one example embodiment shown in FIG. 7 and/or the thickness relationship between the first shield insulating pattern 113 and the second shield insulating pattern 143 according to the at least one example embodiment shown in FIG. 8 may be substantially equally applied.

Accordingly, the arrangement relationship of the first shield pattern SP1, the second shield pattern SP2, the first shield insulating pattern 315, and the second shield insulating pattern 325, and so on may be variously changed.

In the present at least one example embodiment, the first shield pattern SP1 may have a first width W1, and the second shield pattern SP2 may have a second width W2. Here, the first width W1 and the second width W2 may refer to the width in the third direction Z.

Further, each of the first shield capping pattern 317 and the second shield capping pattern 327 may have a first width W1 and a second width W2. For example, the first width W1 may be larger than the second width W2. However, the present disclosure is not limited thereto, and the relationship between the first width W1 and the second width W2 may be variously changed.

Further, in the present at least one example embodiment, the first width W1 may be smaller than the width of the back gate electrode BG in the third direction Z, and the second width W2 may be smaller than the width of the word line WL in the third direction Z. However, the relationship between the first width W1 and the second width W2, the relationship between the first width W1 and the width of the back gate electrode BG, and the relationship between the second width W2 and the width of the word line WL are not limited thereto and may be variously changed.

Unlike the at least one example embodiment shown in FIG. 13, in some example embodiments, due to the thickness difference between the first shield insulating pattern 315 and the second shield insulating pattern 325, as shown in FIG. 8, the first width W1 and the second width W2 may be substantially the same.

Also, unlike the at least one example embodiment shown in FIG. 13, in some example embodiments, the first width W1 may be larger than or the same as (or substantially similar to) the width of the back gate electrode BG in the third direction Z, and the second width W2 may be larger than or the same as (or substantially similar to) the width of the word line WL in the third direction Z.

According to the semiconductor device according to the at least one example embodiment shown in FIG. 12 and FIG. 13, the shield pattern SP is formed between the dopant region of the active pattern AP connected to the cell capacitor DSP, substantially the same effect as that of the semiconductor device according to the above embodiment.

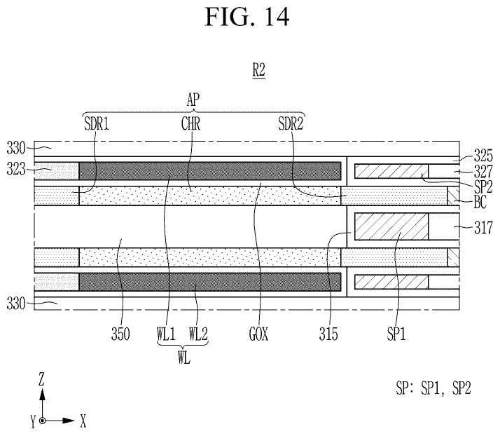

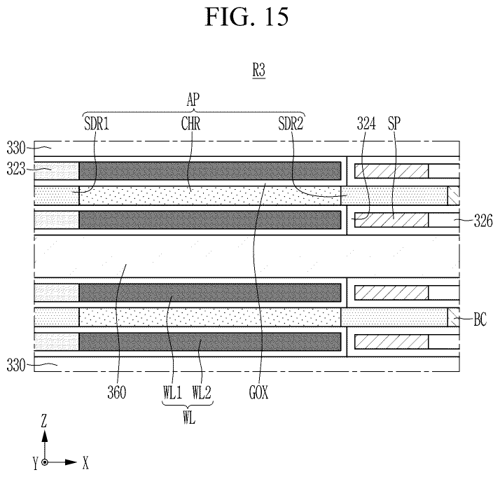

FIG. 14 and FIG. 15 are partial enlarged views illustrating cross-sections of semiconductor devices according to some example embodiments. Specifically, FIG. 14 and FIG. 15 are partial enlarged views illustrating regions R2 and R3 according to some example embodiments which correspond to region R1 of FIG. 12.

According to the semiconductor device according to the at least one example embodiment shown in FIG. 14, unlike the at least one example embodiment shown in FIG. 13, the back gate electrode (see the reference symbol ‘BG’ of FIG. 13), the back gate insulating pattern (see ‘311’ of FIG. 13), and the back gate capping pattern (see the reference symbol ‘313’ of FIG. 13) are omitted, and an isolation insulating pattern 350 positioned between adjacent active patterns AP may be further included.

Specifically, referring to FIG. 14, on one side of any one of the plurality of active patterns AP in the third direction Z, the first word line WL1 may be positioned, and on the other side in the third direction Z, the isolation insulating pattern 350 may be positioned.

Further, on one side of another one of the plurality of active patterns AP in the third direction Z, the isolation insulating pattern 150 may be positioned, and on the other side in the third direction Z, the second word line WL2 may be positioned. In other words, according to the present at least one example embodiment, the word line WL may be positioned only on either one side or the other side of the active pattern AP.

In the present at least one example embodiment, the first shield pattern SP1 may be positioned on the isolation insulating pattern 350, and the second shield pattern SP2 may be positioned on the word line WL. In other words, the first shield pattern SP1 may be positioned to overlap the isolation insulating pattern 350 in the first direction X, and the second shield pattern SP2 may be positioned to overlap the word line WL in the first direction X.

The isolation insulation pattern 350 may contain an insulating material. For example, the insulating material may include silicon oxide, silicon nitride, silicon oxynitride, etc., but is not limited thereto, and may be variously changed.

Besides that, regarding the shield pattern SP according to the present at least one example embodiment, the contents about the shield pattern SP according to the at least one example embodiment shown in FIG. 13 may be substantially equally applied, and thus, a detailed description thereof will not be made.

According to a semiconductor device according to the at least one example embodiment shown in FIG. 15, unlike the at least one example embodiment shown in FIG. 13, the back gate electrode (see the reference symbol ‘BG’ in FIG. 13), the back gate insulating pattern (see the reference symbol ‘311’ in FIG. 13), the back gate capping pattern (see the reference symbol ‘313’ in FIG. 13), the first shield insulating pattern (see the reference symbol ‘315’ in FIG. 13), the first shield capping pattern (see the reference symbol ‘317’ in FIG. 13), and the first shield pattern (see the reference symbol ‘SP1’ in FIG. 13) positioned between adjacent active patterns AP are omitted, and the first word line WL1 and the second word line WL2 are further included between adjacent active patterns AP.

According to the present at least one example embodiment, one stack structure (see the reference symbol “LS” in FIG. 12) may include four word lines WL.

Specifically, on one side in the third direction Z of any one of the plurality of active patterns AP included in one stack structure LS, a first word line WL1 may be positioned, and on the other side in the third direction Z, a second word line WL2 may be positioned.

Further, on one side in the third direction Z of another one of the plurality of active patterns AP, a first word line WL1 may be positioned, and on the other side in the third direction Z, a second word line WL2 may be positioned.

Accordingly, on both sides in the third direction Z of each of the plurality of active patterns AP, word lines WL may be positioned. That is, word lines WL may be positioned on both sides facing each other in the third direction Z among the aspects of a plurality of active patterns AP. In other words, among the side surfaces of the plurality of active patterns AP, two side surfaces facing each other in the third direction Z, word lines WL may be positioned.

The semiconductor device according to the at least one example embodiment may further include a word line isolation pattern 360 which is positioned between a plurality of word lines WL and insulates and isolates them.

The word line isolation pattern 360 may be positioned between word lines WL adjacent in the third direction Z and isolate and insulate the adjacent word lines WL.

For example, the word line isolation pattern 360 may be positioned between the first word line WL1 which is positioned on one side in the third direction Z of any one of the plurality of active patterns AP and the second word line WL2 which is positioned on the other side in the third direction Z of another one of the plurality of active patterns AP.

The word line isolation pattern 360 may contain an insulating material, for example, at least one of silicon nitride, silicon oxynitride, carbon containing silicon oxide, carbon containing silicon nitride, or carbon containing silicon oxynitride.

In the present at least one example embodiment, the plurality of shield pattern SP may be positioned so as to the plurality of word lines WL in the first direction X. In FIG. 15, it is shown that two side surfaces of the side surfaces of each of the plurality of active patterns AP overlap the word line WL, however, the arrangement relationship of each active pattern AP and the word line WL is not limited thereto, and may be variously changed.

Unlike in FIG. 15, in some example embodiments, the word line WL may surround all of the side surfaces of each of the plurality of active patterns AP. For example, the word lines WL1 and WL2 may be integrally formed, and have a gate-all-around (GAA) structure which surrounds four side surfaces of each of the plurality of active patterns AP.

When the word lines WL1 and WL2 are integrally formed and have a structure which surrounds all of the side surfaces of each active pattern AP as described above, the shield pattern SP, the shield insulating pattern 324, and shield capping pattern 326, which are positioned on the first word line WL1 and the second word line WL2, may be integrally formed, respectively, and have a structure which surrounds all of the side surfaces of each active pattern AP.

The semiconductor device according to the at least one example embodiment shown in FIG. 14 may have the same or a substantially similar effect as that of the semiconductor device according to the at least one example embodiment shown in FIG. 10, and the semiconductor device according to the at least one example embodiment shown in FIG. 15 may have the same or a substantially similar effect as that of the semiconductor device according to the at least one example embodiment shown in FIG. 11.

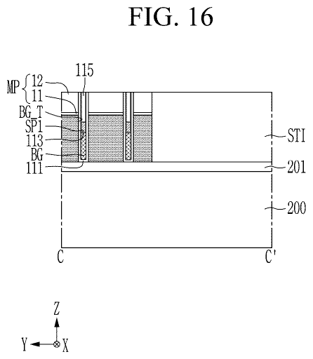

Hereinafter, a method of manufacturing the semiconductor device will be described with reference to FIGS. 16 to 23. Hereinafter, components identical to (or substantially similar) components described above will be denoted by the same reference symbols, and a redundant description thereof will not be made or will be made in brief, and the differences in them from the above-described components will be mainly described.

FIGS. 16 to 23 are cross-sectional views for explaining a method of manufacturing the semiconductor device according to the at least one example embodiment.

Specifically, FIGS. 16 to 23 are cross-sectional views taken along line C-C′ of FIG. 1 in individual manufacturing process steps for explaining the method of manufacturing the semiconductor device according to the at least one example embodiment.

First, referring to FIG. 16, a buried insulating layer 201 and an active layer 202 may be formed on a sub-substrate 200.

Specifically, an insulating layer 201 and an active layer 202 may be formed on a sub-substrate 200. The sub-substrate 200, the buried insulating layer 201, and the active layer 202 may be a silicon-on-insulator substrate (SOI substrate).

The buried insulating layer 201 may be, for example, buried oxide (BOX) formed by a separation by implanted oxygen (SIMOX) method or a bonding and layer transfer method. As another example, the buried insulating layer 201 may be an insulating layer formed by a chemical vapor deposition method.

The buried insulating layer 201 may contain an insulating material, for example, at least one of silicon oxide, silicon nitride, silicon oxynitride, and/or a low-dielectric constant material.

The active layer 202 may be a monocrystalline semiconductor layer. The active layer 202 may be, for example, at least one of a monocrystalline silicon substrate, a germanium substrate, and/or a silicon-germanium substrate.

Subsequently, on the active layer 202, a mask pattern MP may be formed.

The mask pattern MP may include a first mask pattern 11 and a second mask pattern 12 sequentially stacked. The second mask pattern 12 may contain a material having etch selectivity to the first mask pattern 11. For example, the first mask pattern 11 may contain silicon oxide, and the second mask pattern 12 may contain silicon nitride, however, the present disclosure is not limited thereto.

Subsequently, inside the active layer 202, the element isolation layer STI may be formed. The element isolation layer STI may be formed inside the active layer 202 of the peripheral circuit region (see the reference symbol “PAR” in FIG. 3).

The element isolation layer STI may be formed by forming an element isolation trench so as to expose the buried insulating layer 201 by patterning the active layer 202, and then filling an insulating material in the element isolation trench. As the element isolation layer STI is formed, the cell array region (see the reference symbol “CAR” in FIG. 3) may be defined.

Subsequently, the first back gate insulating pattern 111, the back gate electrode BG, the first shield insulating pattern 113, the first shield pattern SP1, and the first shield capping pattern 115 may be sequentially formed.

Specifically, after a back gate trench BG_T is formed by removing some portions of the active layer 202 and the mask pattern MP, the first back gate insulating pattern 111 may be formed on the bottom surface and side surfaces of the back gate trench BG_T.

Subsequently, the back gate electrode BG may be formed by filling the back gate trench BG_T with a conductive material for forming the back gate electrode BG, and then, performing etch back on a portion of the conductive material. The back gate electrode BG may fill a portion of the back gate trench BG_T.

Subsequently, the first shield insulating pattern 113 may be conformally formed along the inner sidewall of the back gate trench BG_T and the upper surface of the back gate electrode BG that is positioned in the back gate trench BG_T.

The first shield insulating pattern 113 may be formed using at least one of an atomic layer deposition (ALD) method, a chemical oxidation (Chemical Oxidation) method, a thermal oxidation (Thermal Oxidation) method, an ultraviolet rays oxidation (UV oxidation) method, a dual plasma oxidation (Dual Plasma Oxidation) method, physical vapor deposition (PVD), thermal chemical vapor deposition (thermal CVD), low-pressure chemical vapor deposition (LP-CVD), and plasma enhanced chemical vapor deposition (PE-CVD) methods. However, the present disclosure is not limited thereto, and the method of forming the first shield insulating pattern 113 may be variously changed.

Subsequently, after the first shield insulating pattern 113 is formed, the remaining space in the back gate trench BG_T is filled with a conductive material for forming the first shield pattern SP1, and a portion of the conductive material may be etched back to form the first shield pattern SP1 on the first shield insulating pattern 113.

In at least one example embodiment, the conductive material for forming the first shield pattern SP1 may include, for example, polysilicon doped with n-type impurity or the metal-containing material having an n-type work function.

The metal-containing material having an n-type work function may include at least one of lanthanum (La), tantalum (Ta), tantalum nitride (TaN), niobium (Nb), or titanium nitride (TiN). However, the present disclosure is not limited thereto, the conductive material for forming the first shield pattern SP1 may be variously changed.

In some example embodiments, after forming the material for the first shield pattern SP1, a gas-phase doping (GPD) process or a plasma doping (PLAD) process may be performed to dope impurity into the first shield pattern (SP1) or to further dope impurity.

The thickness of the first shield pattern SP1 in the third direction Z may be smaller than the thickness of the back gate electrode BG in the third direction Z. The first shield pattern SP1 may fill the portion of the back gate trench BG_T left after the formation of the first shield insulating pattern 113.

Subsequently, after the first shield insulating pattern 113 and the first shield pattern SP1 are formed, the first shield capping pattern 115 may be formed by filling the back gate trench BG_T with an insulating material for forming the first shield capping pattern 115, and then removing a portion of the insulating material by performing an etch-back process or a planarization process, thereby forming the first shield capping pattern 115 on the first shield pattern SP1.

The first shield capping pattern 115 may fill the remaining portion of the back gate trench BG_T left after the formation of the first shield pattern SP1. Here, the remaining back gate trench BG_T space, after forming the first shield pattern SP1, may be defined by the first shield insulating pattern 113.

The upper surface of the first shield capping pattern 115 may be at the same (or a substantially similar) level as that of the upper surface of the mask pattern MP and the element isolation layer STI.

In some example embodiments, before the first back gate insulating pattern 111 is formed, the active layer 202 exposed by the back gate trench BG_T may be doped with an impurity by performing the gas-phase doping (GPD) process or the plasma doping (PLAD) process.

Further, in some example embodiments, the gas-phase doping (GPD) process or the plasma doping (PLAD) process may be performed before forming the first shield pattern SP1 and/or the first shield capping pattern 115. In other words, impurity may be doped into the active layer 202 through the back gate trench BG_T in which the back gate electrode BG is formed. However, the present disclosure is not limited thereto, the process order and method for doping impurity into the active layer 202 may be variously changed.

Here, the impurity may be n-type impurity such as phosphorus (P), arsenic (As), bismuth (Bi), antimony (SB), etc. However, the present disclosure is not limited thereto, the type of impurity doped into the active layer 202 may be variously changed.

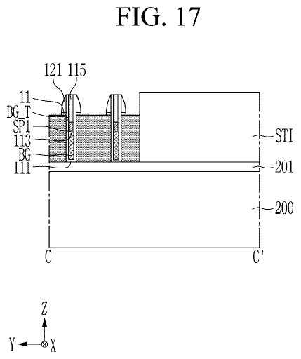

Subsequently, referring to FIG. 16 together with FIG. 17, a pair of spacer patterns 121 may be formed on both side surfaces of the first shield capping pattern 115 positioned in the back gate trench BG_T by removing some portions of the mask pattern MP.

Specifically, the second mask pattern 12 of the mask pattern MP may be removed such that the first mask pattern 11 is exposed. Accordingly, the first shield capping pattern 115 may have a shape protruding from the upper surface of the first mask pattern 11.

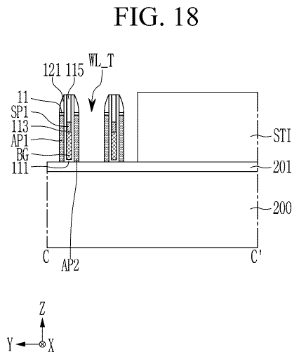

Subsequently, a spacer film (not shown in the drawings) may be formed along the upper surface of the first mask pattern 11, the side surfaces of the first back gate insulating pattern 111, and the upper surface of the first shield capping pattern 115, and then the spacer film may be patterned, whereby the spacer patterns 121 may be formed. Depending on the deposition thickness of the spacer film, the widths of active patterns (see the reference symbols “AP1” and “AP2” in FIG. 18) may be determined.

The spacer film may contain an insulating material. The spacer film may contain, for example, at least one of silicon oxide, silicon oxynitride, silicon nitride, silicon carbide (SiC), and silicon carbonitride (SiCN).

Subsequently, referring to FIG. 17 together with FIG. 18, a pair of first and second active patterns AP1 and AP2 may be formed by patterning the active layer 202.

Specifically, the active layer 202 may be patterned using the spacer patterns 121 as an etch mask. The step of patterning the active layer 202 may include, for example, a step of performing an anisotropic etching process on the active layer 202.

As the active layer 202 is patterned, the pair of first and second active patterns AP1 and AP2 which are positioned on both sides of the back gate electrode BG may be formed. The first and second active patterns AP1 and AP2 may be formed on the side surfaces of the first back gate insulating pattern 111.

In the process step of forming the first and second active patterns AP1 and AP2, as the active layer 202 is removed, the buried insulating layer 201 may be exposed. Although not shown in FIG. 18, in some example embodiments, some portions of the patterned active layer 202 may remain on the side surfaces of the element isolation layer STI.

The first and second active patterns AP1 and AP2 adjacent to each other may define a word line trench WL_T. In other words, the word line trench WL_T may be formed between the first and second active patterns AP1 and AP2 adjacent to each other.

The bottom surface of the word line trench WL_T may be defined by the buried insulating layer 201, and both side walls of the word line trench WL_T may be defined by the first and second active patterns AP1 and AP2.

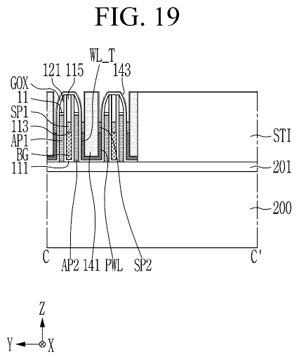

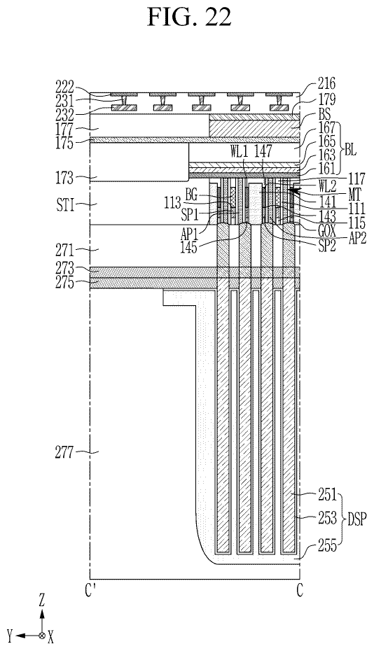

Subsequently, referring to FIG. 18 together with FIG. 19, the gate insulating pattern GOX, and a preliminary word line PWL for forming word lines (see the reference symbols “WL1” and “WL2” in FIG. 22) may be sequentially formed.

The gate insulating pattern GOX may be formed along the bottom surface and side walls of the word line trench WL_T so as to conform to them. The gate insulating pattern GOX may be formed along the side surfaces of the first and second active patterns AP1 and AP2, the upper surface of the first back gate insulating pattern 111, the upper surface of the first shield capping pattern 115, the upper surface of each spacer pattern 121, and the upper surface of the buried insulating layer 201 so as to conform to them.

The gate insulating pattern GOX may be formed using any one of the methods for forming the first shield insulating pattern 113 described above. However, the present disclosure is not limited thereto.

The preliminary word line PWL may be formed along the surface of the gate insulating pattern GOX so as to conform to it. The preliminary word line PWL may be formed along the bottom surface and side walls of the word line trench WL_T so as to conform to them.

The preliminary word line PWL may contain a conductive material. For example, the word line conduction film may contain at least one of doped polysilicon, conductive metal nitrides, conductive metal silicon nitrides, metal carbonitrides, conductive metal silicides, conductive metal oxides, two-dimensional materials, and/or metals.

Subsequently, on the preliminary word line PWL, the gate isolation pattern 141 may be formed, and then some portions of the preliminary word line PWL may be removed.

Specifically, the gate isolation pattern 141 may be formed so as to entirely cover the preliminary word line PWL and fill the word line trench WL_T.

Subsequently, a portion of the gate isolation pattern 141 covering the preliminary word line PWL may be removed such that a portion of the preliminary word line PWL is exposed. In the process step of removing a portion of the gate isolation pattern 141, a portion of the gate insulating pattern GOX may be exposed.

Subsequently, an etching process on the exposed the preliminary word line PWL may be performed.

For example, the etching process on the preliminary word line PWL may be a dry etch-back process.

The etching process on the preliminary word line PWL may be performed until the upper surface of the word line conduction film PWL is positioned at the same (or a substantially similar) level as that of the upper surface of the back gate electrode BG or positioned at a higher level than the upper surface of the back gate electrode BG. However, the present invention is not limited thereto, and in the etching process step on the preliminary word line PWL, the level of the upper surface of the preliminary word line PWL may be variously changed.

As a portion of preliminary word line PWL is removed, the remaining preliminary word line film PWL may have a roughly U-shaped cross section inside the word line trench WL_T. In other words, the remaining preliminary word line PWL may be positioned along the bottom surface and side walls of the word line trench WL_T, and cover the bottom surface of the gate isolation pattern 141 and some portions of the side surfaces adjacent thereto.

As the etching process is performed on the preliminary word line PWL, the upper surface of the preliminary word line PWL may be positioned at a lower level than the upper surface of the gate isolation pattern 141.

Subsequently, the second shield insulating pattern 143 and the second shield pattern SP2 may be sequentially formed on the preliminary word line PWL.

Specifically, the second shield insulating pattern 143 may be formed on the gate isolating pattern GOX, the preliminary word line PWL, and the gate isolation pattern 141 that are positioned in the word line trench WL_T.

The second shield insulating pattern 143 may be conformally formed along the gate insulating pattern GOX, the upper surface of the preliminary word line PWL that is positioned in the word line trench WL_T, the upper surface and side surfaces of the gate isolation pattern 141 that is positioned in the word line trench WL_T, and the upper surface of the element isolation layer STI.

The second shield insulating pattern 143 may be formed using any one of the methods for forming the first shield insulating pattern 113 described above. For example, the second shield insulating pattern 143 may be formed using the atomic layer deposition (ALD) method. However, the present disclosure is not limited thereto, and the method of forming the second shield insulating pattern 143 may be variously changed.

Subsequently, the second shield pattern SP2 may be formed on the second shield insulating pattern 143.

Specifically, after the gate isolating pattern GOX, the preliminary word line PWL, the gate isolation pattern 141, and second shield insulating pattern 143 are formed, a conductive material for forming the second shield pattern SP2 may be filled into the remaining space in the word line trench WL_T, and a portion of the conductive material may be etched back to form the second shield pattern SP2 on the second shield insulating pattern 143.

The conductive material for forming the second shield pattern SP2 may be formed to fill the space between the gate isolating pattern GOX and the gate isolation pattern 141 that are positioned in the word line trench WL_T.

In the process of etching back a portion of the conductive material for forming the second shield pattern SP2, the remaining conductive material is positioned on the upper surface of the preliminary word line PWL that is positioned in the word line trench WL_T and may constitute the second shield pattern SP2.

In at least one example embodiment, the conductive material for forming the second shield pattern SP2 may be the same as the conductive material for forming the first shield pattern SP1 described above. However, the present disclosure is not limited thereto, and the conductive material for forming the first shield pattern SP1 and the conductive material for forming the second shield pattern SP2 may be different.

In some example embodiments, after forming and etching back the material to form the second shield pattern SP2, the gas-phase doping (GPD) process or a plasma doping (PLAD) process may be performed to dope or additionally dope the second shield pattern SP2 with impurity.

The etch back process for the conductive material for forming the second shield pattern SP2 may be performed until the upper surface of the conductive material for forming the second shield pattern SP2 is positioned at substantially the same level as the upper surface of the first shield pattern SP1. However, the present disclosure is not limited thereto, and in the step of performing an etch back process on the conductive material for forming the second shield pattern SP2, the arrangement relationship between the upper surface of the first shield pattern SP1 and the upper surface of the second shield pattern SP2 may be variously changed.

Accordingly, the first shield pattern SP1 and the second shield pattern SP2 may be formed so that the thickness in the third direction Z is substantially the same.

In some example embodiments, any one of the process step of forming the first shield insulating pattern 113 and the first shield pattern SP1 and the process step of forming the second shield insulating pattern 143 and the second shield pattern SP2 may be omitted.

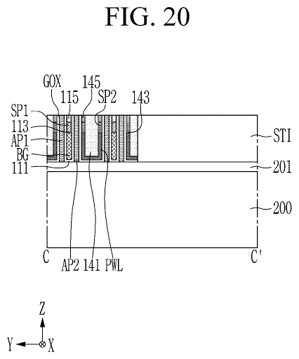

Subsequently, referring to FIG. 20, the second shield capping pattern 145 may be formed on the second shield pattern SP2.

Specifically, the second shield capping pattern 145 may be formed so as to cover the second shield pattern SP2 and the gate isolation pattern 141. The second shield capping pattern 145 may fill the remaining space in the word line trench (see the reference symbol ‘WL_T’ in FIG. 19) after the forming of preliminary word line PWL, gate isolation pattern 141, second shield insulating pattern 143, and second shield pattern SP2.

Subsequently, after forming the second shield capping pattern 145, a planarization process step may be performed. In the step of performing the planarization process, the first mask pattern 11 and each spacer pattern 121 which are positioned on the first and second active patterns AP1 and AP2 may be removed such that the upper surfaces of the first and second active patterns AP1 and AP2 are exposed.

Further, in the step of performing the planarization process, a portion of the first back gate insulating pattern 111, a portion of the first shield capping pattern 115, a portion of the gate insulating pattern GOX, portions of the first and second active patterns AP1 and AP2, a portion of the second shield capping pattern 145, and a portion of the element isolation layer STI may be removed together.

Accordingly, the upper surface of the first back gate insulating pattern 111, the upper surface of the first shield capping pattern 115, the upper surface of the gate insulating pattern GOX, the upper surfaces of the first and second active patterns AP1 and AP2, the second shield capping pattern 145, and the upper surface of the element isolation layer STI may be substantially planarized.

Accordingly, the first shield capping pattern 115 and the second shield capping pattern 145 may be formed so that the thickness in the third direction Z is substantially the same.

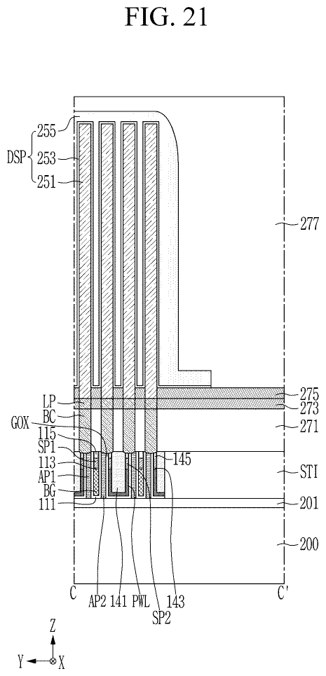

Subsequently, referring to FIG. 21, on the upper surface of the first back gate insulating pattern 111, the upper surface of the first shield capping pattern 115, the upper surface of the gate insulating pattern GOX, the upper surfaces of the first and second active patterns AP1 and AP2, the second shield capping pattern 145, and the upper surface of the element isolation layer STI, the contact interlayer insulating layer 271 which includes a contact hole for explaining the first and second active patterns AP1 and AP2 may be formed.

Subsequently, inside the contact hole of the contact interlayer insulating layer 271, the plurality of storage contact BC may be formed. A plurality of storage contacts BC may be formed on the first and second active patterns AP1, and AP2.

In at least one example embodiment, the storage contact BC may be formed of polysilicon doped with impurity. For example, the storage contact BC may be formed of polysilicon doped with n-type impurity. However, the present disclosure is not limited thereto, and the conductive material for forming the storage contact BC may be variously changed.

In some example embodiments, the process step of forming a storage contact BC may include performing a heat treatment process.

As a result of performing the heat treatment process, some of the impurities included in the storage contact BC may move to the active patterns AP1 and AP2 in contact with the storage contact BC through thermal diffusion.

Accordingly, the concentration of impurity in the active patterns AP1 and AP2 may gradually decrease as they move away from the interface in contact with the storage contact BC.

Subsequently, the pad isolation insulating layer 273 which includes a pad hole may be formed on the contact interlayer insulating layer 271, and then, inside the pad hole of the pad isolation insulating layer 273, the plurality of landing pads LP may be formed. The plurality of landing pads LP may be formed on the plurality of storage contact BC.

Subsequently, on the pad isolation insulating layer 273, the contact etch stop layer 275 may be formed, and then, the first electrode 251 which passes through the contact etch stop layer 275 and be connected to the plurality of landing pads LP, the dielectric film 253 which covers the first electrode 251, and the second electrode 255 which is positioned on the dielectric film 253 may be sequentially formed. The first electrode 251, the dielectric film 253, and the second electrode 255 may constitute a cell capacitor DSP.

Subsequently, the third cell insulating layer 277 which entirely covers the cell capacitor DSP may be formed.

Subsequently, referring to FIG. 21 together with FIG. 22, a back surface lapping step of removing the sub-substrate 200 may be performed. Removing the sub-substrate 200 may include sequentially performing a grinding process and an etching process to expose the buried insulating layer 201.

Subsequently, the buried insulating layer 201 may be removed. As the buried insulating layer 201 is removed, the first and second active patterns AP1 and AP2, the gate insulating pattern GOX, and the first back gate insulating pattern 111 may be exposed.

Subsequently, the gate insulating pattern GOX and the first back gate insulating pattern 111 exposed may be removed. Accordingly, the back gate electrode BG and the preliminary word line PWL may be exposed.

Subsequently, a portion of the back gate electrode BG may be removed by performing an etch back process, and then, the second back gate insulating pattern 117 may be formed on the back gate electrode BG.

Further, a pair of first and second word lines WL1 and WL2 may be formed on both sides of the gate isolation pattern 141 by performing an etch back process or a patterning process for removing a portion of the preliminary word line PWL, and then, the gate capping pattern 147 may be formed so as to cover the first and second word lines WL1 and WL2 and the gate isolation pattern 141.

The process step of forming the second back gate insulating pattern 117 and the gate capping pattern 147 may include a step of performing a planarization process. Accordingly, the first and second active patterns AP1 and AP2, the first back gate insulating pattern 111, the second back gate insulating pattern 117, the gate insulating pattern GOX, and the gate capping pattern 147 may be substantially planarized.

Subsequently, on the active patterns AP1 and AP2, the polysilicon layer 161, the first metal layer 163, the second metal layer 165, and the bit line capping layer 167 may be sequentially formed. The polysilicon layer 161, the first metal layer 163, the second metal layer 165, and the bit line capping layer 167 may constitute a bit line BL.

Subsequently, the second cell insulating layer 173 may be formed on the element isolation layer STI, and then, on the bit line BL and the second cell insulating layer 173, the spacer insulating layer 175, the first cell insulating layer 177, the bit line shield pattern BS, and the bit line shield capping layer 179 may be sequentially formed. However, the order in which the bit line BL, the second cell insulating layer 173, the spacer insulating layer 175, the first cell insulating layer 177, the bit line shield pattern BS, and the bit line shield capping layer 179 are formed is not limited thereto, and may be variously changed.

Subsequently, after forming the second bonding insulating layer 216 on the first cell insulating layer 177 and the bit line shield capping layer 179, the cell connection wiring line 232, the cell connection wiring contact 231, and the second bonding pad 222 may be formed within the second bonding insulating layer 216.

In FIG. 22, it is shown that the second bonding insulating layer 216 is a single layer, however, the second bonding insulating layer 216 may have a structure in which a plurality of layers is stacked, and the plurality of layers may be formed by separate processes.

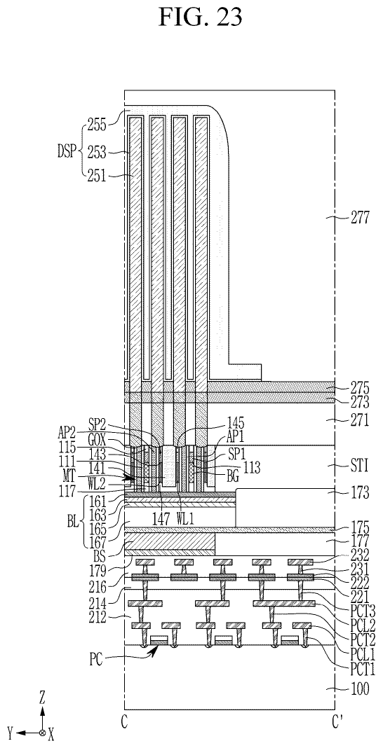

Subsequently, referring to FIG. 3 together with FIG. 23, on the substrate 100, the peripheral circuit structure PS which includes the peripheral circuit PC, the peripheral circuit contacts PCT1, PCT2, and PCT3, the peripheral circuit wiring lines PCL1 and PCL2, the peripheral circuit insulating layer 212, the first bonding insulating layer 214, and the first bonding pad 221 may be formed.

Subsequently, the first bonding pad 221 and the second bonding pad 222 may be bonded such that the peripheral circuit structure PS formed on the substrate 100 and the bit line BL face each other, and the first bonding insulating layer 214 and the second bonding insulating layer 216 may be bonded together. Accordingly, the first bonding pad 221 and the second bonding pad 222 may be in contact with each other to form a metal bond, and the first bonding insulating layer 214 and the second bonding insulating layer 216 may be in contact with each other to form a junction insulating layer.

Subsequently, inside the third cell insulating layer 277, the first cell wiring contact 261 and the first cell wiring line 262 may be formed. Subsequently, on the third cell insulating layer 277, the fourth cell insulating layer 279, the second cell wiring contact 263 and the second cell wiring line 264 may be formed.

While this disclosure has been described in connection with what is presently considered to be some examples of practical embodiments, it is to be understood that the invention and/or inventive concepts are not limited to the disclosed embodiments. On the contrary, it is intended to cover various modifications and equivalent arrangements included within the spirit and scope of the appended claims.

What is claimed is:

1. A semiconductor device comprising:
a substrate;
a bit line on the substrate, the bit line extending in a first horizontal direction;
a plurality of word lines on the bit line, the plurality of word lines each extending in a second horizontal direction intersecting the first horizonal direction;
a first active pattern and a second active pattern between the plurality of word lines such that the first active pattern and the second active pattern are spaced apart in the first horizontal direction;
one or more cell capacitors, the one or more cell capacitors including at least one cell capacitor on at least one of the first active pattern or the second active pattern; and
a plurality of shield patterns at a level between a level of the plurality of word lines and a level of the one or more cell capacitors,
wherein each of the first active pattern and the second active pattern includes
a first dopant region connected to the bit line,
a second dopant region connected to the one or more cell capacitors, and
a channel region that is between the first dopant region and the second dopant region,
the plurality of shield patterns includes at least one of a shield pattern that overlaps the second dopant region of the first active pattern in the first horizontal direction or a shield pattern that overlaps the second dopant region of the second active pattern in the first horizontal direction, and
the plurality of shield patterns includes at least one of a metal-containing material having an n-type work function or a polysilicon doped with an impurity.

2. The semiconductor device of claim 1, wherein a work function of the plurality of shield patterns is less than or substantially equal to a work function of the second dopant region.

3. The semiconductor device of claim 2, further comprising:
one or more storage contacts, the one or more storage contacts including at least one of a storage contact between the first active pattern and the one or more cell capacitors or a storage contact between the second active pattern and the one or more cell capacitors,
wherein the work function of the plurality of shield patterns is greater than or substantially equal to the work function of one or more the storage contacts.

4. The semiconductor device of claim 1, wherein the plurality of shield patterns on the plurality of word lines.

5. The semiconductor device of claim 1, further comprising:
a back gate electrode between the first active pattern and the second active pattern, the back gate electrode extending in the second horizontal direction.

6. The semiconductor device of claim 5, wherein the plurality of shield patterns includes:
a first shield pattern on the back gate electrode, and
a second shield pattern on the plurality of word lines.

7. The semiconductor device of claim 6, wherein
a width of the first shield pattern is smaller than a width of the back gate electrode, and
a width of the second shield pattern is smaller than a width of each of the plurality of word lines.

8. The semiconductor device of claim 6, wherein
a width of the first shield pattern and a width of the second shield pattern are different.

9. The semiconductor device of claim 6, further comprising:
one or more storage contacts, the one or more storage contacts including at least one of a storage contact between the first active pattern and the one or more cell capacitors or a storage contact between the second active pattern and the one or more cell capacitors,
the first shield pattern includes a first surface adjacent to the back gate electrode and a second surface adjacent to the one or more the storage contacts,
the second shield pattern includes a first surface adjacent to the plurality of word lines and a second surface adjacent to the one or more storage contacts, and
the second surface of the first shield pattern and the second surface of the second shield pattern are at different levels from each other.

10. The semiconductor device of claim 6, wherein:
the plurality of word lines includes a first word line and a second word line that are adjacent to each other, and
the second shield pattern is on the first word line and the second word line.

11. The semiconductor device of claim 1, further comprising:
an isolation insulating pattern between the first active pattern and the second active pattern,
wherein the plurality of shield patterns includes
a first shield pattern on the isolation insulating pattern, and
a second shield pattern on the plurality of word lines.

12. The semiconductor device of claim 1, wherein:
the impurity is an n-type impurity.

13. The semiconductor device of claim 1, wherein:
the metal-containing material having the n-type work function includes at least one of lanthanum (La), tantalum (Ta), tantalum nitride (TaN), niobium (Nb), titanium nitride (TiN), or a combination thereof.

14. A semiconductor device comprising:
a substrate;
a bit line on the substrate, the bit line extending in a first horizontal direction;
a plurality of word lines on the bit line, the plurality of word lines extending in a second horizontal direction intersecting the first horizontal direction;
a first active pattern and a second active pattern between the plurality of word lines such that the first active pattern and the second active pattern are spaced apart in the first horizontal direction;
a back gate electrode between the first active pattern and the second active pattern, the back gate electrode extending in the second horizontal direction;
one or more storage contacts, the one or more storage contacts including at least one of a storage contact on the first active pattern or a storage contact on the second active pattern;
one or more cell capacitors on the one or more storage contacts; and
a plurality of shield patterns on at least one of the plurality of word lines and the back gate electrode,
wherein each of the first active pattern and the second active pattern includes:
a first dopant region connected to the bit line,
a second dopant region connected to the storage contact, and
a channel region between the first dopant region and the second dopant region,
the plurality of shield patterns includes at least one of a shield pattern overlapping the second dopant region of the first active pattern in the first horizontal direction or a shield pattern overlapping the second dopant region of the second active pattern in the first horizontal direction, and
a work function of the plurality of shield patterns is less than or substantially equal to a work function of the second dopant region.

15. The semiconductor device of claim 14, wherein the work function of the plurality of shield patterns is greater than or substantially equal to a work function of the one or more storage contacts.

16. The semiconductor device of claim 14, wherein
each of the plurality of shield patterns, the second dopant region of the first active pattern, and the second dopant region of the second active pattern include an n-type impurity, and
a concentration of the n-type impurity in the plurality of shield patterns is greater than or substantially equal to a concentration of the n-type impurity in at least one of the second dopant region of the first active pattern or of the second dopant region of the second active pattern.

17. The semiconductor device of claim 14, wherein each of the plurality of shield patterns includes a first surface and a second surface facing each other in a vertical direction, the vertical direction intersecting the first horizontal direction and the second horizontal direction, and
wherein the semiconductor device further comprises
a shield capping pattern the first surface of at least one of the plurality of shield patterns, and
a shield insulating pattern surrounding the second surface and both side surfaces of the at least one of the plurality of shield patterns, and side surfaces of the shield capping pattern.

18. A semiconductor device comprising:
a substrate;
a bit line on the substrate, the substrate extending in a first horizontal direction;
a plurality of word lines on the bit line, the plurality of word lines extending in a second horizontal direction intersecting the first horizontal direction;
a plurality of active patterns positioned between the plurality of word lines such that the plurality of active patterns are spaced apart in the first horizontal direction,
a back gate electrode between the plurality of active pattern, the back gate electrode extending in the second horizontal direction;
at least one storage contact on the plurality of active pattern;
at least one cell capacitor on the at least one storage contact; and
a plurality of shield patterns, the plurality of shield patterns including a first shield pattern on the back gate electrode, and a second shield pattern on the plurality of word lines,
wherein each of the plurality of active pattern includes
a first dopant region connected to the bit line,
a second dopant region connected to the storage contact, and
a channel region between the first dopant region and the second dopant region,
the plurality of shield patterns each overlap, in the first horizontal direction, the second dopant region of at least one corresponding active pattern of the plurality of active patterns,
the first shield pattern and the second shield pattern include at least one of a metal-containing material having an n-type work function or a polysilicon doped with n-type impurity,
a work function of each of the first shield pattern and the second shield pattern is lower than or substantially equal to a work function of the second dopant region of the corresponding active pattern, and
the work function of each of the first shield pattern and the second shield pattern is greater than or substantially equal to a work function of the at least one storage contact.

19. The semiconductor device of claim 18, wherein:
a width of the first shield pattern and a width of the second shield pattern are substantially the same.

20. The semiconductor device of claim 18, wherein a thickness of the first shield pattern extending in a third direction and a thickness of the second shield pattern extending in the third direction are different from each other, and
the third direction intersects the first horizontal direction and the second horizontal direction.
